(19) United States
(12) Patent Application Publication
(10) Pub. No.: US 2022/0247393 A1
(43) Pub. Date: Aug. 4, 2022

(54) HIGH ACCURACY LOW POWER SMALL AREA CMOS CURRENT STARVED RING OSCILLATOR WITH NOVEL COMPENSATION TECHNIQUES FOR SUPPLY, TEMPERATURE AND PROCESS DEPENDENCY

(71) Applicant: Vidatronic, Inc., Austin, TX (US)

(72) Inventors: Bishoy Milad HELMY ZAKY, Cairo (EG); Sameh Ahmed Assem IBRAHIM, Cairo (EG); Hazem Hassan Mohamed HAMMAM, Cairo (EG); Anand VEERAVALLI RAGHUPATHY, Plano, TX (US); Moises Emanuel ROBINSON, Austin, TX (US)

(73) Assignee: Vidatronic, Inc., Austin, TX (US)

(21) Appl. No.: 17/727,684

(22) Filed: Apr. 22, 2022

Related U.S. Application Data
(63) Continuation of application No. 17/497,871, filed on Oct. 8, 2021.
(60) Provisional application No. 63/089,500, filed on Oct. 8, 2020.

(51) Int. Cl. H03K 3/03; H03K 17/687

(52) U.S. Cl. CPC H03K 3/0315; H03K 17/6872

(57) ABSTRACT

An apparatus includes a poly current generator circuit, which includes a fractional bandgap circuit, or a bandgap voltage reference circuit and a current reference generator, an adaptive bias current generator, a frequency generator to generate an output clock signal having a select frequency, wherein the frequency generator includes a current starved ring oscillator that comprises n identical cascaded stages connected in a shape of a ring, wherein an output of the nth cascaded stage is fed back as an input of the first cascaded stage, wherein n is an odd number greater than or equal to 3; and clock buffers configured to buffer the output clock signal generated by the frequency generator for distribution.

### CROSS REFERENCE TO RELATED APPLICATION

This is a Continuation Application and claims the benefits of application Ser. No. 17/497,871, filed on Oct. 8, 2021, which claims the benefit of Provisional Application No. 63/089,500, filed on Oct. 8, 2020. The disclosures of these prior applications incorporated by reference in their entirety.

### BACKGROUND

An oscillator is a circuit that generates a clock signal with a certain frequency to be used by the other circuits. There are many families of oscillators including LC-based oscillators, RC-based oscillators, and all-CMOS oscillators. One of the famous all-CMOS oscillators is the ring oscillator. The main advantage of the ring oscillator is its ability to generate very high frequencies while consuming small chip area. The main challenge of this type of oscillators is the frequency variation versus the supply and temperature.

FIG. 1 shows a schematic block level diagram of a simple current starved ring oscillator (100). The oscillator consists of odd number of stages. Each stage is a current starved inverter (113) that is biased by (nbias) (110) and (pbias) (111), wherein the needed bias, (nbias) (110) and (pbias) (111), are generated using a bias current (I_Bias) (107). There is also a capacitor (C) (115) added at the output of each stage. The current value inside each current starved inverter (I_inv) (114) is determined by the current mirror ratio following the given relation:

$$\frac{I\_Inv}{I\_Bias} = \frac{Size Mn\_S 1}{Size Mn\_nbias \_L} = \frac{Size Mp\_S 1}{Size Mp\_pbias} .$$

The frequency of the oscillator output clock (116) is dependent on the supply value (VDD), current value inside each current starved inverter (I_inv) (114), capacitor value (C) (115), and the number of stages (N) following the given relation:

$$Frequency = \frac{I\_Inv}{N * VDD * Ctot} ,$$

wherein (Ctot) is the total capacitance at the output of each stage including the value of the added capacitance (C) (115), parasitic routing capacitance, output capacitance of the current starved inverter stage (MOSFET drain/source capacitance) and the input capacitance of the next stage (MOSFET gate capacitance). The main disadvantage of this circuit is the variation of the frequency of the oscillator output clock (116) versus supply (VDD) variation, versus temperature variation, and versus process variation.

FIG. 2A shows the oscillator output clock frequency variations versus the supply (VDD) (200) for a simple current starved ring oscillator (using a constant ideal current as the bias current I_Bias) for all process & temperature corners. The oscillator is designed to have a typical output clock frequency of 360 MHz. It is clear that the oscillator output clock frequency is inversely proportional to the supply (VDD) for all process & temperature corners.

FIG. 2B shows the oscillator output clock frequency variations versus the supply (VDD) (at a typical temperature) for a simple current starved ring oscillator (using a constant ideal current as the bias current I_Bias) for the two extreme MOSFET process corners: slow MOSFET corner (SS) (220) and fast MOSFET corner (FF) (221). The oscillator is designed to have a typical output clock frequency of 360 MHz. We can notice that the oscillator output clock frequencies decrease with supply (VDD); the fast MOSFET corner (FF) (221) has a steeper slope than that of the slow MOSFET corner (SS) (220). This can be explained as follows. In the case of the fast MOSFET corner (FF) (221), the threshold of the MOSFET devices inside the oscillator stages decreases, and this allows more short circuit current to pass during the switching activity at higher supply in the case of fast MOSFET corner (FF) (221) as compared to the case of the slow MOSFET corner (SS) (220) such that the current going to charge the capacitors in between the stages decreases, which decreases more the frequency of the oscillator output clock in the case of fast MOSFET corner (FF) (221).

FIG. 3 shows the oscillator output clock frequency variation versus temperature (300) for a simple current starved ring oscillator (using a constant ideal current as the bias current I_Bias) for all process and supply (VDD) corners. The oscillator is designed to have a typical output clock frequency of 360 MHz. It is clear that the oscillator output clock frequency is inversely proportional to the temperature for all process and supply (VDD) corners.

It is clear from the above analysis that for a current starved ring oscillator (which uses a constant ideal current as the bias current I_Bias), its output clock frequency is inversely proportional to both the supply (VDD) and the temperature. There have been attempts to improve the ring oscillator performance. The following techniques will focus mainly on these two issues.

FIG. 4 shows a schematic block level diagram of a system (400) including a bandgap voltage reference circuit (422), a current reference generator (424) and a current starved ring oscillator (405). The bandgap circuit (422) is used to generate a voltage reference (Vbgref) (423). The current reference generator (424) takes the (Vbgref) (423) and uses it to generate a poly reference current by dividing the voltage reference (Vbgref) (423) over the resistor (R_poly) (426), thereby generating (Vbgref/R_poly) poly current (425). Then, the generated poly current (425) is used as the bias current of the oscillator (405). The generated poly current (425) is independent of the supply (VDD) variation and has very small variation (or nearly constant) versus the temperature. The main disadvantage of this system is the variation of the frequency of the oscillator output clock (416) versus supply (VDD) and versus temperature. Another disadvantage is that we need to trim the resistor (R_poly) (426) to get the same value of the bias current (poly current) (425) versus the process variation, so that we can get the same frequency of the oscillator output clock (416).

FIG. 5 shows a schematic block level diagram of a system (500) including a PTAT current reference generator (545) and a current starved ring oscillator (505). The PTAT current reference generator (545) generates a PTAT current (546) that is directly proportional to temperature. The value of generated PTAT current (546) follows the given relation:

$$PTAT current = \frac{2 * {( 1 - \frac{1}{\sqrt{M}} )}^{2}}{{µ}_{n} * Cox {( \frac{W}{L} )}_{n} * {R\_ptat}^{2}} ,$$

wherein (M) is the ratio of the size of the NMOS transistor (Mn_ptat_R) (550) to the size of the NMOS transistor (Mn_ptat_L) (551). The generated PTAT current (546) is used as the bias current of the oscillator (505). Therefore, the frequency of the oscillator output clock (516) tends to be directly proportional to the temperature (due to using the PTAT current only as the bias current). There is also a PMOS diode connected transistor (Mp_reg) (502) that is used as a simple regulator generating a regulated supply (Vreg) (501) for the oscillator (505). The regulated supply (Vreg) (501) helps to decrease the oscillator output clock (516) frequency variation versus the variation of the main supply (VDD). Another benefit of that PMOS diode connected transistor (Mp_reg) (502) is that: as the temperature increases, its Vsg (source-gate voltage) decreases a little bit, so that the value of (Vreg) (501) increases a little bit, which in turn decreases the frequency a little bit (because for a current starved ring oscillator, the frequency is inversely proportional to the supply value). As a result, the oscillator output clock (516) frequency is almost constant across the temperature.

In sum, as the temperature increases, the generated PTAT bias current (546) increases (which tends to increase the frequency), and at the same time, the (Vreg) (501) increases a little bit (which tends to decrease the frequency a little bit). As a result of that, the frequency of the output clock (516) is nearly constant across the temperature range. This is one of the advantages of this system. The main disadvantages include the variations of the regulated supply (Vreg) (501) due to the main supply (VDD) variations, which will cause frequency variations, and the large size of the cap (C_reg) (504) used for this regulated supply (Vreg) (501) in order to sustain the same voltage value (Vreg) (501) during the high frequency current spikes drawn by the oscillator (505) during the switching activities. Another disadvantage is that it is necessary to trim the resistor (R_ptat) (549) to get the same value of the bias current (generated PTAT current) (546) versus the process variations, so that we can get the same frequency of the oscillator output clock (516).

FIG. 6 shows a schematic block level diagram of a system (600) including a supply dependent bias current generator (657) generating a bias current that is a function of the supply (VDD) and a current starved ring oscillator (605). The generated supply dependent bias current (I1) (659) is used as the bias current of the current starved ring oscillator (605). The supply dependent bias current generator (657) includes three parts: the first part is one generating current (IA) (658), which is equal to

$$\frac{V D D - V t}{R 1} ,$$

wherein (Vt) is the gate-source voltage for the NMOS transistor (Mn_nbias_L) (612). The current (IA) (658) is generated when the supply (VDD) value is larger than the value (Vt), and the current (IA) (658) is directly proportional to the supply (VDD). The second part is a circuit generating current (I2) (660), which is equal to

$$\frac{V D D - 3 V t}{R 2} ,$$

wherein (Vt) is the source-gate voltage for each one of the PMOS transistors (Mp_1_I2) (663), (Mp2_I2) (664), and (Mp3_I2) (665), assuming that these three transistors are similar. The current (I2) (660) is generated when the supply (VDD) value is larger than (3 Vt), and it is directly proportional to the supply (VDD) with a different slope compared to the slope of the current (IA) (658). The third part is to subtract the current (I2) (660) from the current (IA) (658) to generate the current (I1) (659), which is equal to (IA-I2). The current (I1) (659) is used as the bias current for the oscillator (605).

The current (I1) (659) is equal to (IA) (658) when the supply (VDD) value is within the range of (from Vt to 3 Vt) because within that supply range, the current (I2) (660) equals zero. When the value of the supply (VDD) is larger than (3 Vt), the current (I2) (660) is generated such that the current (I1) (659) is equal to (IA-I2). Therefore, the generated current (I1) (659) is directly proportional to the supply (VDD) with a steep slope when the supply (VDD) value is within the range of from Vt to 3 Vt, and it has a small slope versus supply (VDD) when the supply (VDD) value is larger than (3 Vt). The aim of such profile is to compensate the frequency variations of the oscillator output clock (616) for the variations of the supply (VDD) (because the frequency of a current starved ring oscillator is inversely proportional to the supply), while limiting the generated bias current (I1) (659) value when the value of the supply (VDD) is large (i.e., larger than 3 Vt) and also limiting the frequency of the oscillator output clock (616).

FIG. 7 shows a profile of the generated currents (700) in the supply dependent bias current generator (657) in the system (600) of FIG. 6. We can see that the (IA) (758) is generated when the supply (VDD) value is larger than (Vt) and it is directly proportional to the supply (VDD). We can see the current (I2) (760) is generated when the supply (VDD) value is larger than (3 Vt) with a different slope compared to the slope of the current (IA) (758). We can see that the generated current (I1) (759) is equal to the current (IA) (758) when the supply (VDD) value is within the range of from Vt to 3 Vt, and it has a steep slope versus supply (VDD) in that range. Then, the current (I1) (759) equals (IA-I2) when the supply (VDD) value is larger than (3 Vt), so that it has a small slope versus supply (VDD) in that range (i.e., at higher supply).

One disadvantage in the system (600) of FIG. 6 is that the supply-dependent bias current generator (657) is complicated and needs multiple resistors (which consume area and current). Another disadvantage is that the generated supply-dependent bias current depends on the values of the resistor (R1) (661) and resistor (R2) (662), and therefore each one of the resistors needs to be trimmed to get the same value of the generated bias current versus the resistor process variation in order to get the same oscillator output clock (616) frequency. Another disadvantage in the system is that the frequency variation of the oscillator output clock (616) versus temperature is still not compensated.

FIG. 8 shows a schematic block level diagram of a system (800) including a PTAT voltage reference generator (843), a voltage regulator circuit (803) and a ring oscillator (806). The PTAT voltage reference generator (843) generates a PTAT voltage reference (844). It also has a startup circuit (848) that is used at the startup of the system. The generated PTAT voltage reference (844) is used as the voltage reference of the regulator (803). Therefore, the regulated supply (Vreg) (801) generated by the voltage regulator (803) is directly proportional to the temperature. The regulated supply (Vreg) (801) is used as the supply for the ring oscillator (806). Thus, this loop has multiple advantages. One advantage is that the (Vreg) (801) is nearly constant versus the variation of the main supply (VDD), and therefore the oscillator output clock (816) frequency variation versus the main supply (VDD) variation is very small. Another advantage is that the (Vreg) (801) versus temperature profile nearly compensates the oscillator output clock (816) frequency variation versus temperature. Because for a simple ring oscillator, the frequency is directly proportional to the supply and inverse proportional to the temperature. Therefore, as the temperature increases, the regulated supply (Vreg) (801) increases, so that the frequency tends to increase to compensate for the inverse proportionality between the frequency and the temperature mentioned above. The main disadvantages of this system include the area and power consumed by the voltage regulator (803). The size of the cap (C_reg) (804) used for this regulated supply (Vreg) (801) has to be large to be able to sustain the same voltage value (Vreg) (801) during the high frequency current spikes drawn by the oscillator (806) during the switching activity.

While these prior art systems provide satisfactory ring oscillators, there is still a need for better systems that have good performance with respect to variations in supply, temperature, and process corners.

### SUMMARY OF THE INVENTION

Embodiments of the invention relate to system architectures for current starved ring oscillators. A current starved ring oscillator of the invention has a very small frequency variation in the oscillator output clock versus the supply, temperature, and process variations. In addition, these systems use very small areas and currents.

In accordance with embodiments of the invention, a current starved ring oscillator comprises a bandgap voltage reference circuit; a current reference generator; an adaptive bias current generator; a frequency generator; and clock buffers. The bandgap voltage reference circuit is configured to generate a bandgap voltage reference, which serves as an input to the current reference generator. The current reference generator uses the bandgap voltage reference to generate a poly current through a regulation loop that includes a resistor and an error amplifier, wherein the generated poly current has a value that depends on a value of the resistor and the bandgap voltage reference, such that the value of the generated poly current is independent of a supply (VDD) and has a small variation versus temperature variations. The poly current generated by the current reference generator is provided as an input to the adaptive bias current generator. The adaptive bias current generator generates an adaptive bias current that is adaptive to variations in supply, temperature, and process such that a value of the generated adaptive bias current changes based on the variations in the supply, temperature, and process. The generated adaptive bias current is provided as an input to the frequency generator, wherein the frequency generator uses the generated adaptive bias current as a bias current of the frequency generator. The frequency generator comprises a current starved ring oscillator having n identical cascaded stages connected in a shape of a ring and generating an output clock signal having a certain frequency such that an output of the nth stage is fed back as an input of the first stage, wherein n is an odd number greater than or equal to 3 (e.g., 3, 5, 7, 9, 11, etc.), wherein each of the n identical cascaded stages is a current starved inverter, which comprises an inverting module, an NMOS current source, and a PMOS current source. The clock buffers are used to buffer the output clock signal that is generated by the frequency generator; so that the clock can be distributed to the whole system.

In accordance with some embodiments of the invention, the frequency generator comprises a current starved ring oscillator having n identical cascaded stages connected in a shape of a ring, wherein n is an odd number greater than or equal to 3, and.

### BRIEF DESCRIPTION OF DRAWINGS

FIG. 1 shows a schematic block level circuit diagram of a prior art current starved ring oscillator showing the parameters controlling the frequency of the oscillator output clock.

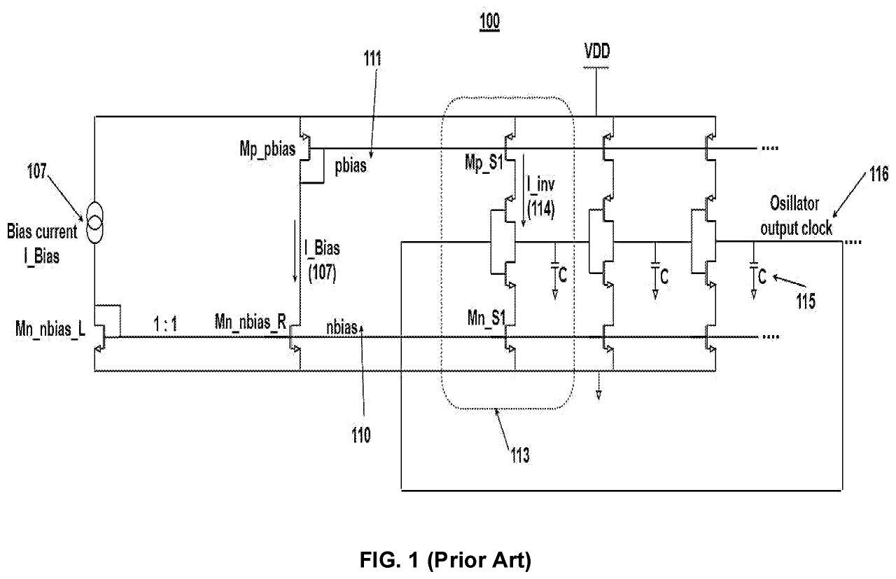

FIG. 2A shows an oscillator output clock frequency variation versus supply for a simple current starved ring oscillator for all process & temperature corners.

FIG. 2B shows an oscillator output clock frequency variation versus supply (at typical temperature) for a simple current starved ring oscillator for the two extreme MOSFET process corners: slow MOSFET corner (SS) and fast MOSFET corner (FF).

FIG. 3 shows an oscillator output clock frequency variation versus temperature for a simple current starved ring oscillator for all process & supply corners.

FIG. 4 shows a schematic block level circuit diagram of a prior art system including a bandgap voltage reference circuit, a current reference generator and a current starved ring oscillator. The voltage reference (Vbgref) generated by the bandgap voltage reference circuit is used to generate (Vbgref/R_poly) poly current, which is used as the bias current of the oscillator.

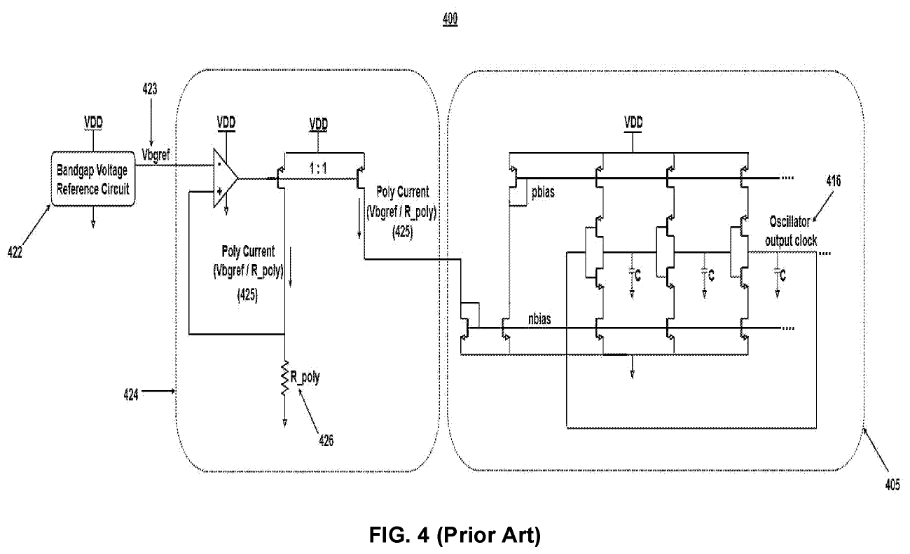

FIG. 5 shows a schematic block level circuit diagram of a prior art system including a PTAT current reference generator and a current starved ring oscillator, wherein the generated PTAT current is used as the bias current of the oscillator.

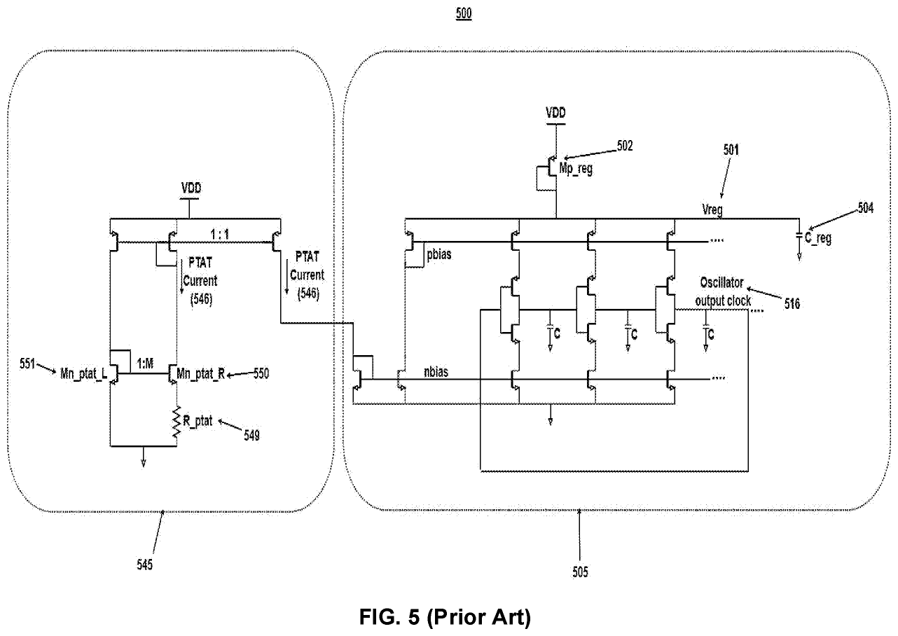

FIG. 6 shows a schematic block level circuit diagram of a prior art system including a supply dependent bias current generator generating a supply dependent bias current that is a function of the supply and a current starved ring oscillator wherein the generated supply dependent bias current is used as the bias current of the oscillator.

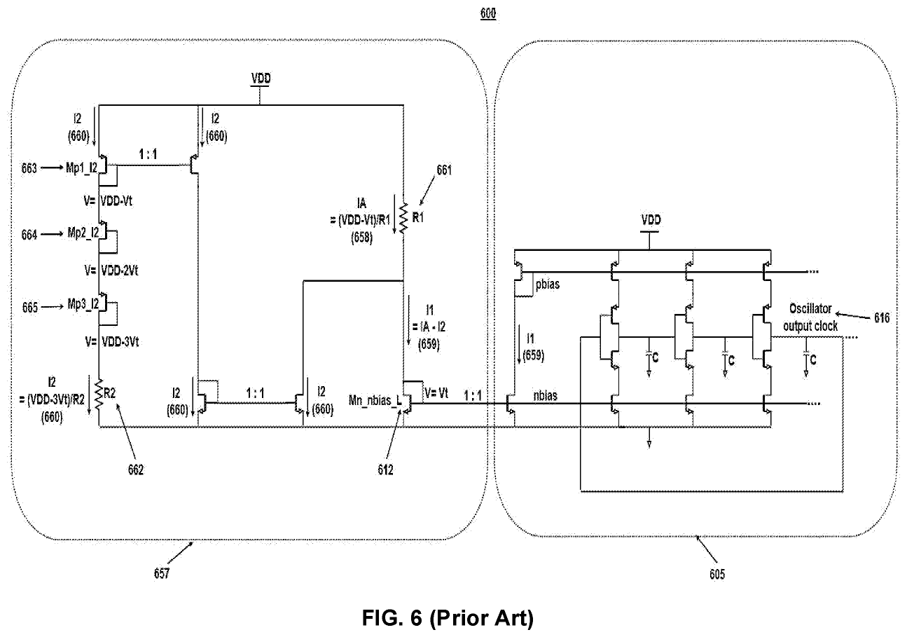

FIG. 7 shows a profile of the currents generated by the supply dependent bias current generator in the system of FIG. 6.

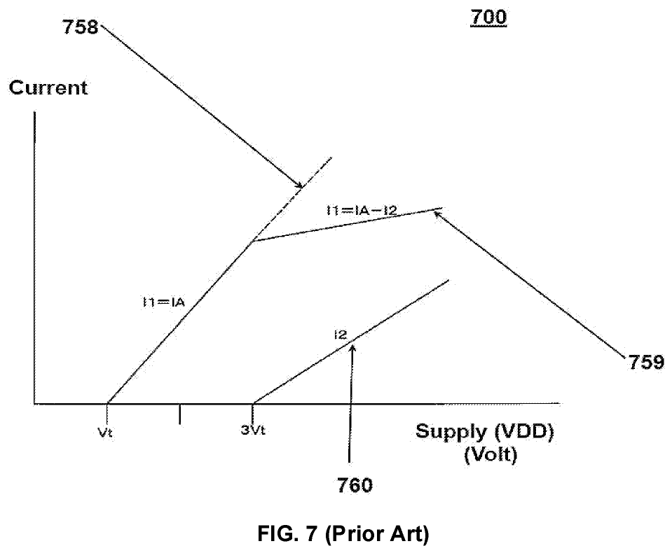

FIG. 8 shows a schematic block level circuit diagram of a prior art system including a PTAT voltage reference generator, a voltage regulator circuit and a ring oscillator. The generated PTAT voltage reference is used as the reference of the regulator. The regulated supply generated by the regulator (Vreg) is used as the supply for the ring oscillator.

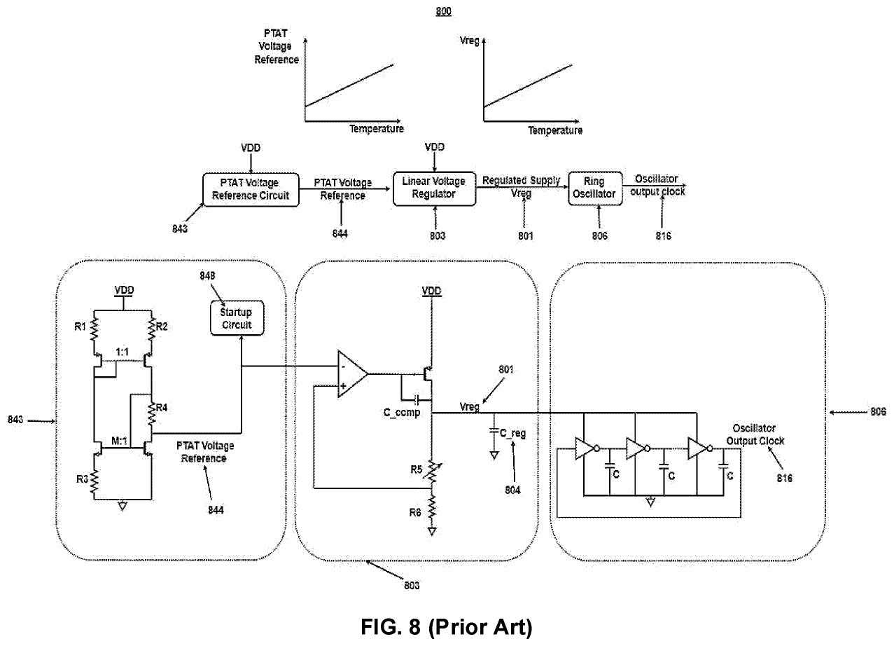

FIG. 9 shows a simplified schematic block level circuit diagram of a system in accordance with one embodiment of the invention. The system includes a bandgap voltage reference circuit, a current reference (Vbgref/R) generator, an adaptive bias current generator, a current starved ring oscillator, and clock buffers.

FIG. 10 shows a detailed schematic block level circuit diagram of a system in accordance with one embodiment of the invention. The system includes a bandgap voltage reference circuit, a current reference (Vbgref/R) generator, an adaptive bias current generator, a current starved ring oscillator, and clock buffers.

FIG. 11 shows a schematic block level circuit diagram of an adaptive bias current generator including four circuits, which are Poly current weighting circuit, Poly current trimming circuit, Temperature dependent bias current generator, and Supply & Process dependent bias current generator.

FIG. 12 shows a schematic block level circuit diagram of a Poly current weighting circuit.

FIG. 13A shows a plot of variation of the poly current versus supply for all process and temperature corners.

FIG. 13B shows a plot of variation of the poly current versus temperature for all process and supply corners.

FIG. 14 shows a simplified schematic block level circuit diagram of the Poly current trimming circuit.

FIG. 15 shows a detailed schematic block level circuit diagram of a Poly current trimming circuit which is a binary weighted (n bits) current DAC.

FIG. 16 shows a schematic block level circuit diagram of a Temperature dependent bias current generator.

FIG. 17A shows a plot of variation of the weighted temperature dependent bias current (weighted PTAT bias current) versus temperature for all process and supply corners.

FIG. 17B shows a plot of variation of the weighted temperature dependent bias current (weighted PTAT bias current) versus supply for all process and temperature corners.

FIG. 18 shows a schematic block level circuit diagram of a Supply & Process dependent bias current generator.

FIG. 19A shows a profile of the weighted supply & process dependent bias current versus the supply for all process and temperature corners.

FIG. 19B shows a profile of the weighted supply & process dependent bias current versus the supply at a typical temperature for the two MOSFET process corners: slow MOSFET corner (SS) and fast MOSFET corner (FF).

FIG. 20 shows a profile of the weighted supply & process dependent bias current versus the temperature for all process and supply corners.

FIG. 21 shows a plot of untrimmed frequency variation of the oscillator output clock in the system of FIG. 10 versus the supply for all process and temperature corners.

FIG. 22 shows a plot of variation of the untrimmed frequency of the oscillator output clock in the system of FIG. 10 versus temperature for all process and supply corners.

FIG. 23 shows a plot of variation of the trimmed frequency of the oscillator output clock in the system of FIG. 10 versus the supply for all process and temperature corners after doing the trimming.

FIG. 24 shows a plot of variation of the trimmed frequency of the oscillator output clock in the system of FIG. 10 versus the temperature for all process and supply corners after doing the trimming.

FIG. 25 shows a flow chart that illustrates the design steps and the operation of the current starved ring oscillator using an adaptive bias technique that compensates the oscillator output clock frequency variation versus supply, temperature, and process.

FIG. 26 shows a summary of the design steps and the operation of the current starved ring oscillator using an adaptive bias technique that compensates the oscillator output clock frequency variation versus supply, temperature, and process.

### DETAILED DESCRIPTION

Aspects of the present disclosure are shown in the above-identified drawings and are described below. In the description, like or identical reference numerals are used to identify common or similar elements. The drawings are not necessarily to scale and certain features may be shown exaggerated in scale or in schematic in the interest of clarity and conciseness.

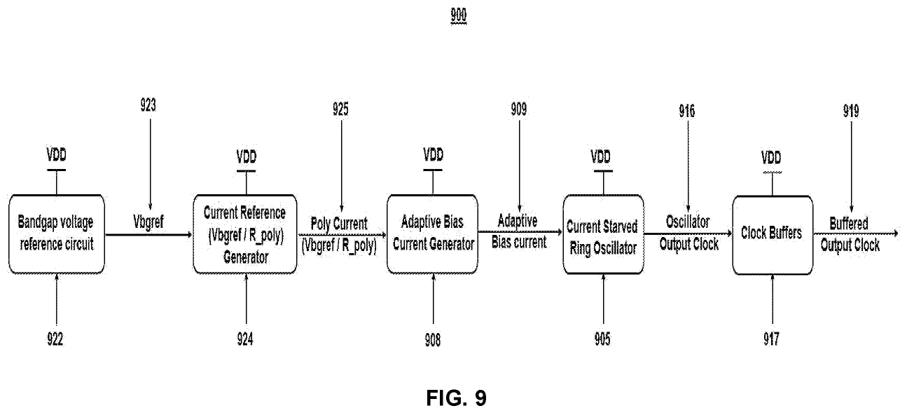

Embodiments of the invention relate to current starved ring oscillators that have better controls of frequency variations with respect to supply, temperature, and process variations. FIG. 9 shows a simplified schematic block level circuit diagram of a system (900) in accordance with one embodiment of the invention. In this example, system (900) includes a bandgap voltage reference circuit (922), a current reference generator (924), an adaptive bias current generator (908), a current starved ring oscillator (905), and clock buffers (917).

The bandgap voltage reference circuit (922) is used to generate a voltage reference (Vbgref) (923). The current reference generator (924) takes the (Vbgref) (923) and uses it to generate a poly current (925). The bandgap voltage reference circuit is a circuit that generates a voltage reference independent of the supply, temperature, and process corners. The bandgap voltage reference circuit architecture can be any topology, such as a traditional bandgap or a fractional bandgap circuit. If the bandgap voltage reference circuit (922) is a fractional bandgap circuit that can generate a poly current directly, then the current reference generator (924) is unnecessary. In other words, a fractional bandgap circuit may replace the combination of a traditional bandgap voltage reference circuit (922) and a current reference generator (924).

The poly current (925) generated by the bandgap voltage reference circuit (922) is provided as an input to the adaptive bias current generator (908). The adaptive bias current generator (908) takes the generated poly current (925) to generate an adaptive bias current (909) that is adaptive to variations in supply, temperature, and process such that a value of the adaptive bias current changes based on the variations in the supply, the temperature, and the process. The adaptive bias current generator (908) may generate an adaptive bias current by performing a trimming of the poly current and then adds the trimmed poly current internally to another type of current in certain weights to generate the adaptive bias current (909). The adaptive bias current (909) is then used as a bias current of the current starved ring oscillator (905) to output an oscillator output clock (916). The oscillator output clock (916) is then buffered by some clock buffers (917) to generate a buffered output clock (919).

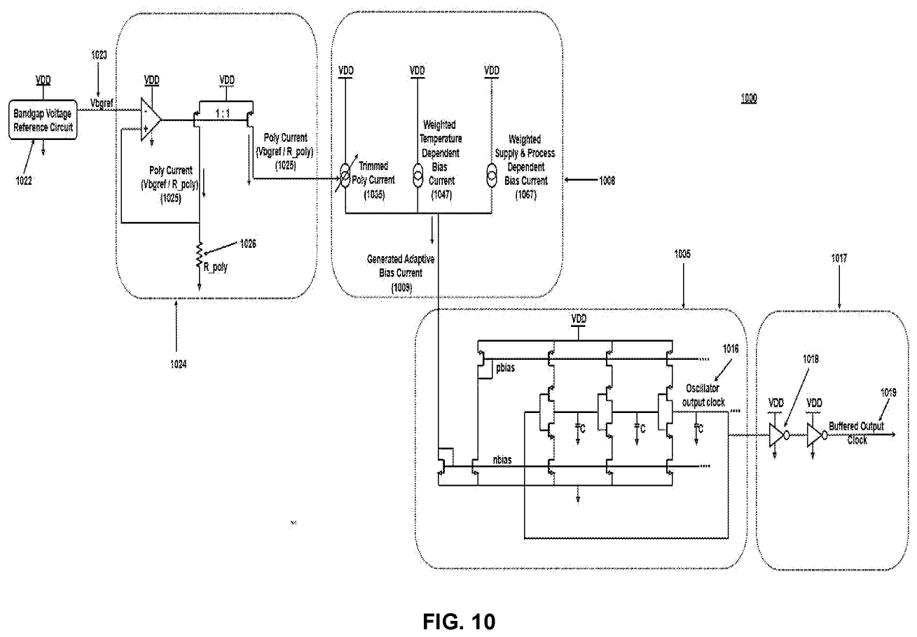

FIG. 10 shows 1 detailed schematic block level circuit diagram of a system (1000) in accordance with one embodiment of the invention. In this example, the system includes a bandgap voltage reference circuit (1022), a current reference (Vbgref/R_poly) generator (1024), an adaptive bias current generator (1008), a current starved ring oscillator (1005), and clock buffers (1017). The bandgap circuit (1022) is used to generate a bandgap voltage reference (Vbgref) (1023). The bandgap voltage reference circuit architecture can be any topology, such as a traditional bandgap or a fractional bandgap circuit. The bandgap voltage reference circuit can be implemented using resistors and BJTs, or it can be all CMOS bandgap voltage reference circuit.

If the bandgap voltage reference circuit (1022) is a fractional bandgap circuit that can generate a poly current, then a current reference generator (1024) is unnecessary. If the bandgap voltage reference circuit (1022) is a traditional bandgap circuit, then a current reference generator (1024) is used. The current reference generator (1024) may comprise a regulation loop, which comprises a resistor and an error amplifier. The current reference generator (1024) uses the regulation loop and the bandgap voltage reference (Vbgref) (1023) to generate the poly current (1025), by dividing the bandgap voltage reference (Vbgref) (1023) over the resistor (R_poly) (1026). The resulting poly current (1025), (Vbgref/R_poly), has a value that depends on a value of the resistor and the bandgap voltage reference, but is independent of a supply (VDD).

The adaptive bias current generator (1008) takes the generated poly current (1025), generates an internal weighted copy of it, and performs a trimming for it (to adjust the oscillator output clock frequency versus process corners) to generate a trimmed poly current (1035). Then, the adaptive bias current generator (1008) adds three types of currents together in certain weights such that the total generated bias current (1009) is adaptive to the supply, temperature, and process variations. Herein, “adaptive to” means a value of the adaptive bias current changes based on the variations in the supply, the temperature, and the process. The three types of currents are the trimmed poly current (1035), a weighted temperature dependent bias current (1047), and a weighted supply and process dependent bias current (1067).

Then, the generated adaptive bias current (1009) is used as a bias current of the current starved ring oscillator (1005). The aim of such generated adaptive bias is to compensate the oscillator output clock (1016) frequency variation versus the variation of the supply (VDD), temperature, and process corners. The current starved ring oscillator may comprise n identical cascaded stages connected in a shape of a ring, wherein an output of the nth cascaded stage is fed back as an input of the first cascaded stage, wherein n is an odd number greater than or equal to 3.

The oscillator output clock (1016) is then buffered by clock buffers (1017) to generate a buffered output clock (1019). The clock buffers block (1017) comprises simple inverters (1018) to buffer the clock to be distributed and used inside the whole system.

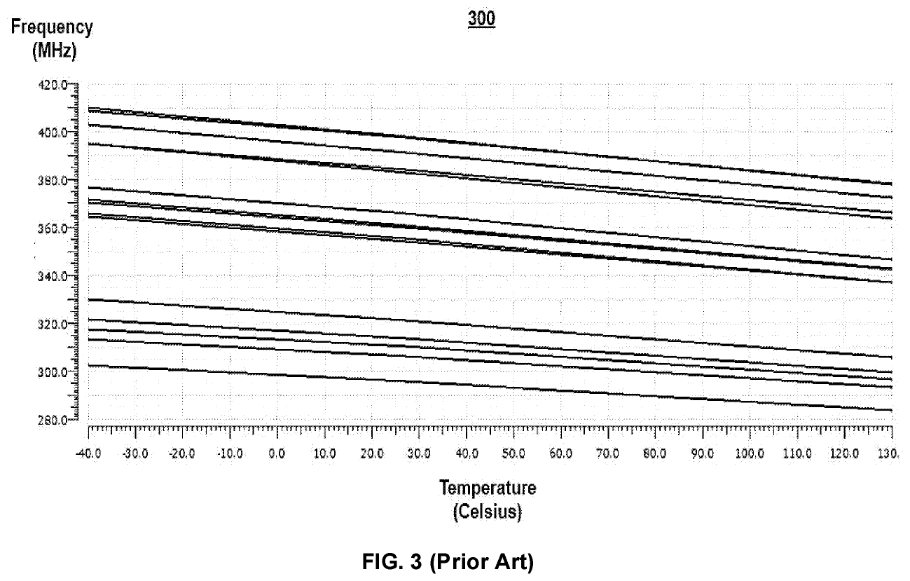

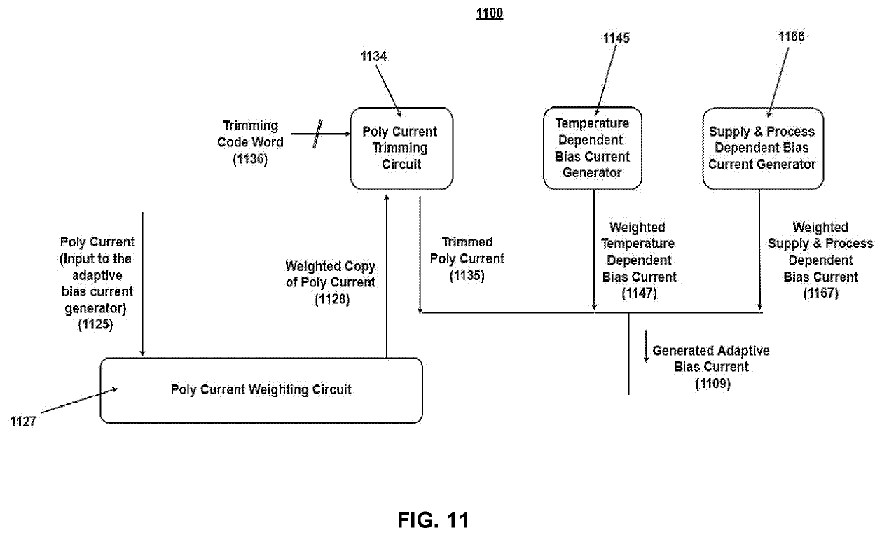

FIG. 11 shows a schematic block level circuit diagram of an adaptive bias current generator (1100) in accordance with one embodiment of the invention. The adaptive bias current generator (1100) includes four circuits. The first one is a Poly current weighting circuit (1127), which takes the previously generated poly current (Vbgref/R_poly) (1125) and creates an internal weighted copy of it (1128). The second one is a Poly current trimming circuit (1134), which takes the weighted copy of the poly current (1128) and a suitable trimming code word (1136) to generate a trimmed poly current (1135) through a current DAC. The third one is a Temperature dependent bias current generator (1145), which generates a weighted temperature dependent bias current (1147) that is a function of the temperature and its value is independent of the supply variations. Generally, the weighted temperature dependent bias current (1147) can be a proportional to absolute temperature (PTAT) current or a complementary to absolute temperature (CTAT) current. In this exemplary system, the generated weighted temperature dependent bias current is a weighted PTAT current (because the current starved ring oscillator output clock frequency is inversely proportional to the temperature in the employed technology as described with reference to FIG. 3). The fourth one is a Supply and Process dependent bias current generator (1166), which generates a weighted temperature dependent bias current (1167) that is directly proportional to the supply and its value and slope are dependent on the process corners. Therefore, there are three types of generated currents, which are the trimmed poly current (1135), the weighted temperature dependent bias current (1147), and the weighted supply and process dependent bias current (1167). These three generated types of currents are added together in certain weights to generate a total adaptive bias current (1109) that is used to bias the current starved ring oscillator.

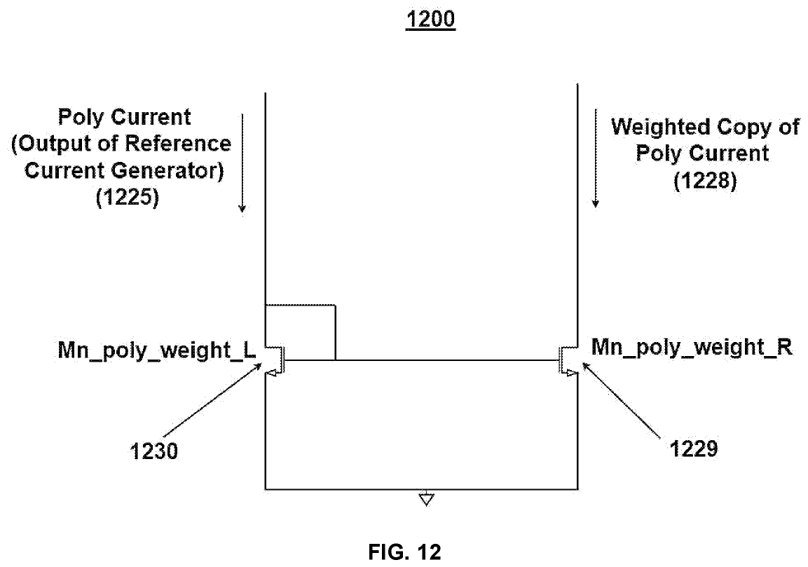

FIG. 12 shows a schematic block level circuit diagram of a Poly current weighting circuit (1200). In this example, the Poly current weighting circuit (1200) is a current mirror, which can be a simple current mirror or a cascade current mirror. The Poly current weighting circuit (1200) takes the poly current (1225) generated from the current reference generator (as an input) and generates a weighted copy of the poly current (1228). The generated weighted copy of poly current (1228) depends on the ratio between the size of the transistor Mn_poly_weight_R (1229) and the size of the transistor Mn_poly_weight_L (1230). The ratio can be obtained using the following relation:

$$\frac{\begin{matrix}Weighted Copy of Poly \\ Current ( Output )\end{matrix}}{Poly Current ( Input )} = \frac{Size Mn\_poly \_weight \_R}{Size Mn\_poly \_weight \_L} .$$

The generated current (1228) will be used as an input for the Poly current trimming circuit.)

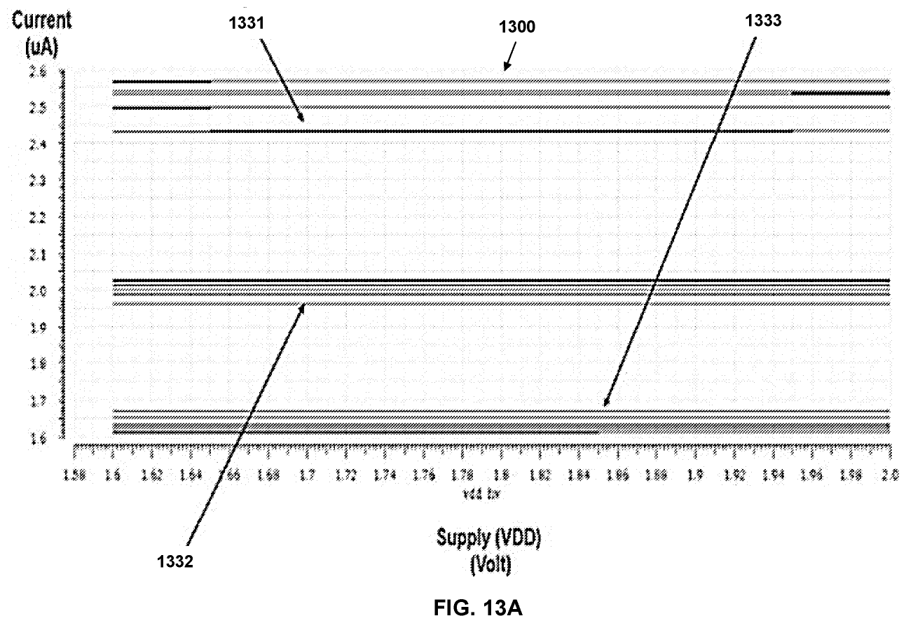

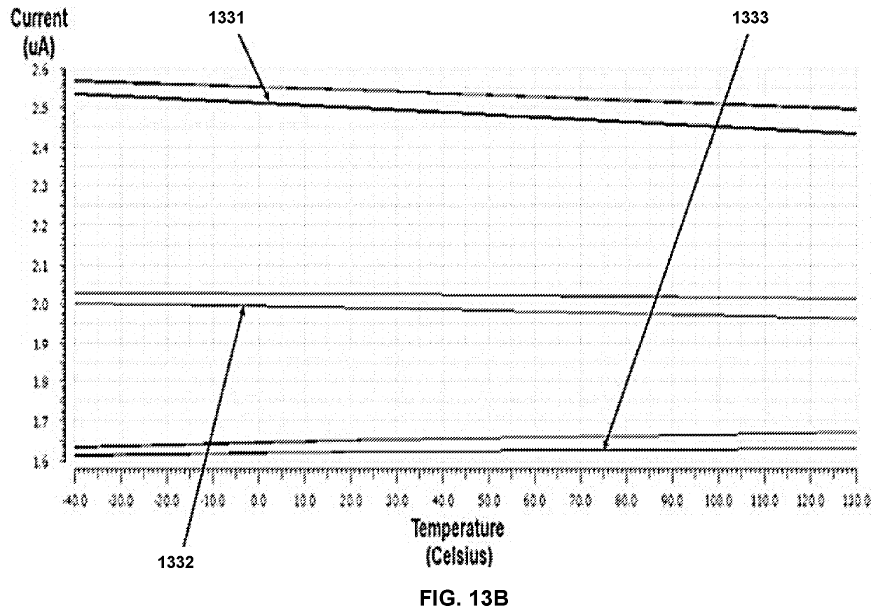

FIG. 13A shows a plot of variations of the poly current (Vbgref/R_poly) versus the supply (VDD) for all process and temperature corners (1300). It is very clear that the poly current values are independent of the supply (VDD) variations. However, the values of the poly current are affected by the process corners of the resistor (R_poly) inside the current reference generator. In FIG. 13A, the upper bundle of curves (1331) represents the fast corner of the resistor, wherein the generated poly currents are large. The middle bundle of curves (1332) represents the typical corner of the resistor. The lower bundle of curves (1333) represents the slow corner of the resistors, wherein the generated poly currents are small.

FIG. 13B shows a plot of variation of the poly current (Vbgref/R_poly) versus the temperature for all process and supply (VDD) corners. It is very clear that the poly current values have very small variations versus the temperature. This is due to the temperature coefficient of the resistor (R_poly) inside the current reference generator, wherein the resistor (R_poly) value has a very small variation versus temperature. The three bundles of curves represent the three process corners of the resistor (R_poly) as mentioned above.

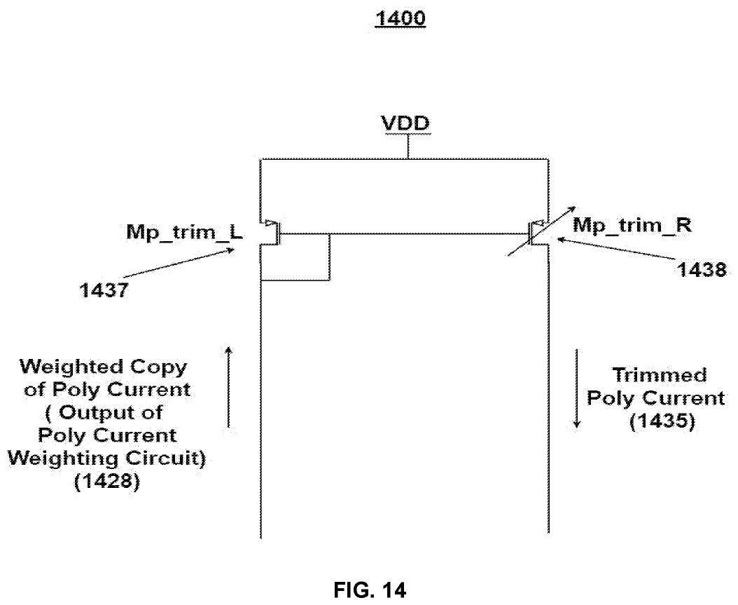

FIG. 14 shows a simplified schematic block level circuit diagram of a Poly current trimming circuit (1400). It is a current mirror, which can be a simple or cascade current mirror with an adjustable ratio. The weighted copy of the poly current (1428) (generated by the poly current weighting circuit) is provided as an input for the left diode connected PMOS transistor (Mp_trim_L) (1437), and the output trimmed poly current (1435) is taken from the right PMOS transistor (Mp_trim_R) (1438). The output trimmed poly current (1435) is determined by the ratio of the size of the two transistors following the given relation:

$$\frac{Trimmed Poly Current ( Output )}{\begin{matrix}Weighted Copy of Poly \\ Current ( Input )\end{matrix}} = \frac{Size Mp\_trim \_R}{Size Mp\_trim \_L} .$$

The right transistor (Mp_trim_R) (1438) has an adjustable size (based on the provided trimming code word). Increasing its size means increasing the output trimmed poly current (1435), and decreasing its size means decreasing the output trimmed poly current (1435).

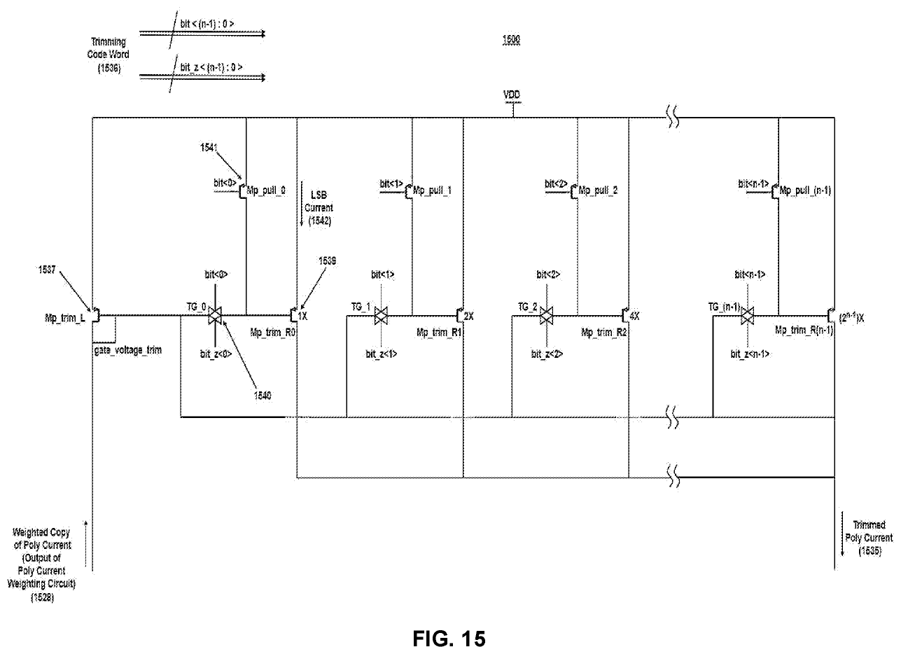

FIG. 15 shows a detailed schematic block level circuit diagram of a Poly current trimming circuit (1500). It is a binary weighted (n bits) current DAC. It takes the weighted copy of the poly current (1528) (generated by the poly current weighting circuit) as an input current and takes the provided trimming code word (1536) as well. It produces the trimmed poly current (1535) as an output based on the provided trimming code word (1536). The weighted copy of the poly current (1528) is provided as an input for the left diode connected PMOS transistor (Mp_trim_L) (1537) to generate its gate voltage (gate_voltage_trim). The (n) output transistors (Mp_trim_R0, Mp_trim_R1, Mp_trim_R2 . . . Mp_trim_R(n−1)) on the right side have binary weighted sizes starting from 1×, 2×, 4× . . . (2ⁿ⁻¹)×. They are connected in parallel with each other, wherein each output transistor has a different gate connection. The gate of each output transistor has two different connections, which are a transmission gate (TG) and a pull up PMOS transistor (Mp_pull). Each output transistor has its control signal to turn it on or off based on the provided trimming code word (1536). If the control signal (e.g.,: bit<0> from trimming code word) is high, that means that the output transistor (Mp_trim_R0) (1539) will be on, its pull up PMOS transistor (Mp_pull_0) (1541) will be off, and its transmission gate (TG_0) (1540) will be on, so that the gate of that output transistor (Mp_trim_R0) (1539) will be connected to the gate of the diode connected PMOS transistor (Mp_trim_L) (1537), so that output transistor provides an output current based on its weight (size). If the control signal (e.g.,: bit<0>from trimming code word) is low, that means that the output transistor (Mp_trim_R0) (1539) will be off, its transmission gate (TG_0) (1540) will be off, and its pull up PMOS transistor (Mp_pull_0) (1541) will be on, so that the gate of that output transistor (Mp_trim_R0) (1539) will be pulled to supply (VDD), so that it is off.

The current in the LSB output transistor (Mp_trim_R0) (1539) can be obtained from the following relation:

$$\frac{Trimmed Poly Current LSB}{\begin{matrix}Weighted Copy of Poly \\ Current ( Input )\end{matrix}} = \frac{Size Mp\_trim \_R 0}{Size Mp\_trim \_L} .$$

The output trimmed poly current can be obtained from the following relation:

$$\frac{Trimmed Poly Current ( Output )}{\begin{matrix}Weighted Copy of Poly \\ Current ( Input )\end{matrix}} = \frac{\begin{matrix}( Size MP\_trim \_R 0 * bit 〈 0 〉 ) + ( Size MP\_trim \_R 1 * bit 〈 1 〉 ) + \\ ( Size MP\_trim \_R 2 * bit 〈 2 〉 ) … + ( Size MP\_trim \_R ( n - 1 ) * bit 〈 n - 1 〉 )\end{matrix}}{Size Mp\_trim \_L}$$

Wherein bit<0> is the value of the LSB in the trimming code word and bit<n−1> is the value of MSB in the trimming code word for (n bits) current DAC.

The aim of the Poly current trimming circuit (shown as 1134 in FIG. 11) is to trim the frequency of the oscillator output clock at the desired frequency across all process corners. For example, if the oscillator output clock frequency is lower than expected, the Poly current trimming circuit increases the output trimmed poly current (based on the provided trimming code word), thereby the total generated adaptive bias current increases so that the frequency increases and reaches the desired value. In another example, if the oscillator output clock frequency is higher than expected, the Poly current trimming circuit decreases the output trimmed poly current (based on the provided trimming code word), thereby the total generated adaptive bias current decreases, such that the frequency decreases and reaches the desired value.

It is worth to mention that the untrimmed oscillator output clock frequency is affected by the process corner of the MOSFET and the resistor. For example, in the case of the slow corner of the resistor, the generated poly current (Vbgref/R_poly) by the current reference generator decreases, so the untrimmed frequency of the oscillator output clock decreases. The same idea applies for the MOSFET process corners, wherein the MOS capacitance and the short circuit current are affected by the MOSFET process corner that affects the oscillator output clock frequency.

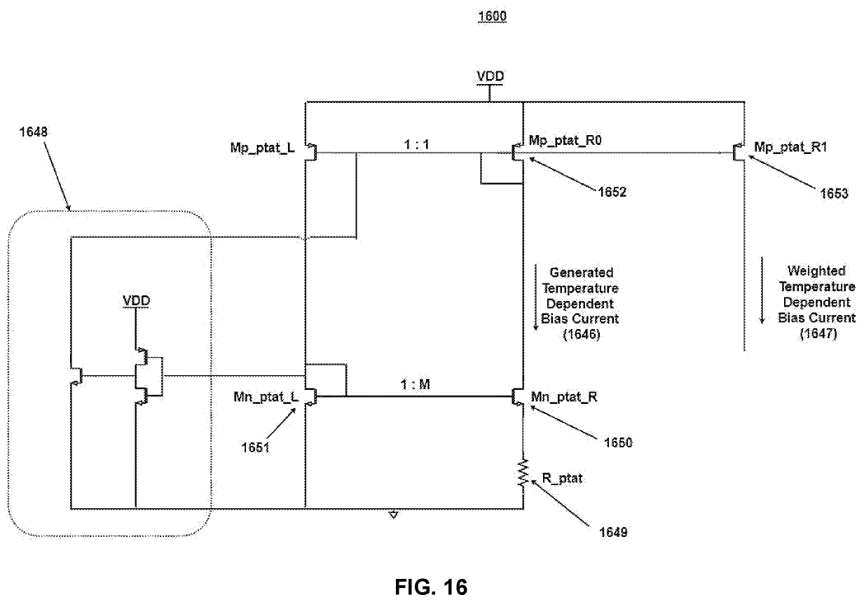

FIG. 16 shows a schematic block level circuit diagram of a Temperature dependent bias current generator (1600), which generates a weighted temperature dependent bias current (1647) that is a function of the temperature and its value is independent of the supply variations. Generally, the temperature dependent bias current can be a PTAT current or CTAT current. In the exemplary system shown, the temperature dependent bias current is a PTAT bias current, which means that its value is directly proportional to the temperature (because the current starved ring oscillator output clock frequency is inversely proportional to the temperature in the used technology as discussed with reference to FIG. 3) and its value is independent of the supply (VDD) variations.

The PTAT bias current generator (a temperature dependent bias current generator) is a constant transconductance (GM) bias circuit. The generated current (1646) value depends on the value of the resistor (R_ptat) (1649) following the equation:

$$Generated temperature dependent bias current = \frac{2 * {( 1 - \frac{1}{\sqrt{M}} )}^{2}}{{µ}_{n} * Cox {( \frac{W}{L} )}_{n} * {R}_{ptat}^{2}}$$

wherein (M) is the ratio of the size of the NMOS transistor (Mn_ptat_R) (1650) to the size of the NMOS transistor (Mn_ptat_L) (1651). A weighted copy of the generated temperature dependent bias current (1647) is generated to be used in the oscillator bias current. The weight of the weighted temperature dependent bias current (1647) is adjusted through adjusting the ratio between the size of the PMOS transistor (Mp_ptat_R1) (1653) and the size of the PMOS transistor (Mp_ptat_R0) (1652) following the relation:

$$\frac{\begin{matrix}Weighted temperature dependent \\ bias current ( Output )\end{matrix}}{Generated temperature dependent bias current} = \frac{Size Mp\_ptat \_R 1}{Size Mp\_ptat \_R 0} .$$

The circuit also has a startup circuit (1648) that is turned off once the circuit is up.

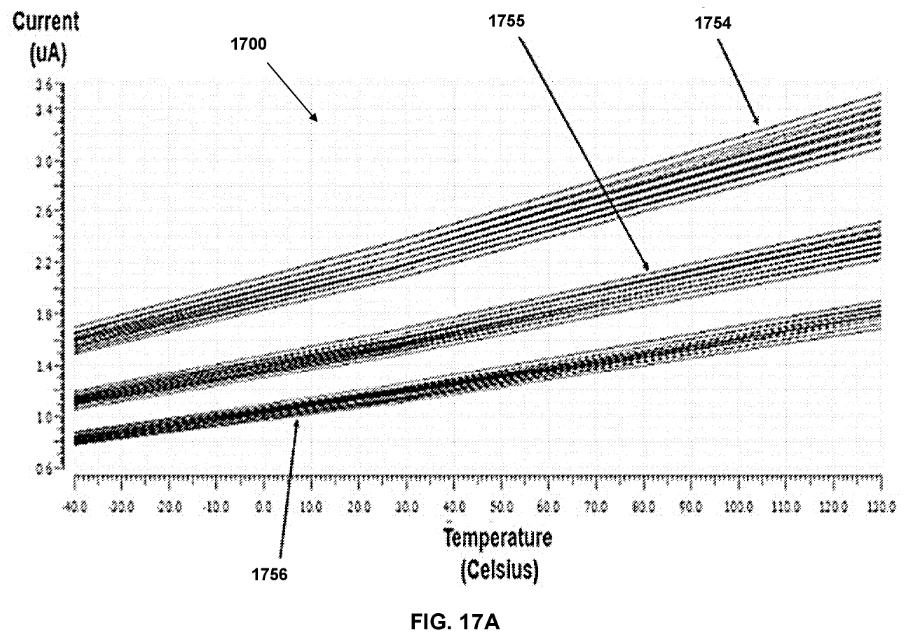

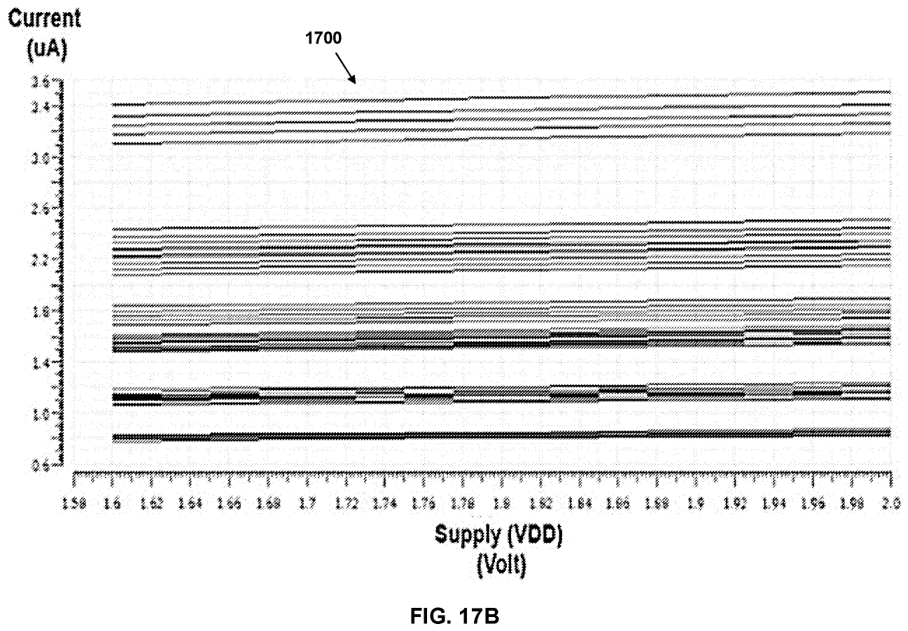

FIG. 17A shows a plot of the variation of the weighted temperature dependent bias current (weighted PTAT bias current) versus temperature for all process and supply (VDD) corners (1700). It is clear that the value of the weighted PTAT bias current is directly proportional to the temperature across all corners. However, we can see that the value of the weighted PTAT bias current is affected by the resistor (R_ptat) process corners. The upper bundle of curves (1754) represents the fast corner of the resistor, wherein the weighted PTAT bias current is large. The middle bundle of curves (1755) represents the typical corner of the resistor. The lower bundle of curves (1756) represents the slow corner of the resistors, wherein the weighted PTAT bias current is small.

FIG. 17B shows the variation of the weighted temperature dependent bias current (weighted PTAT bias current) versus supply (VDD) for all process and temperature corners. It is clear that the weighted PTAT bias current value has very small variation versus the supply (VDD) variation.

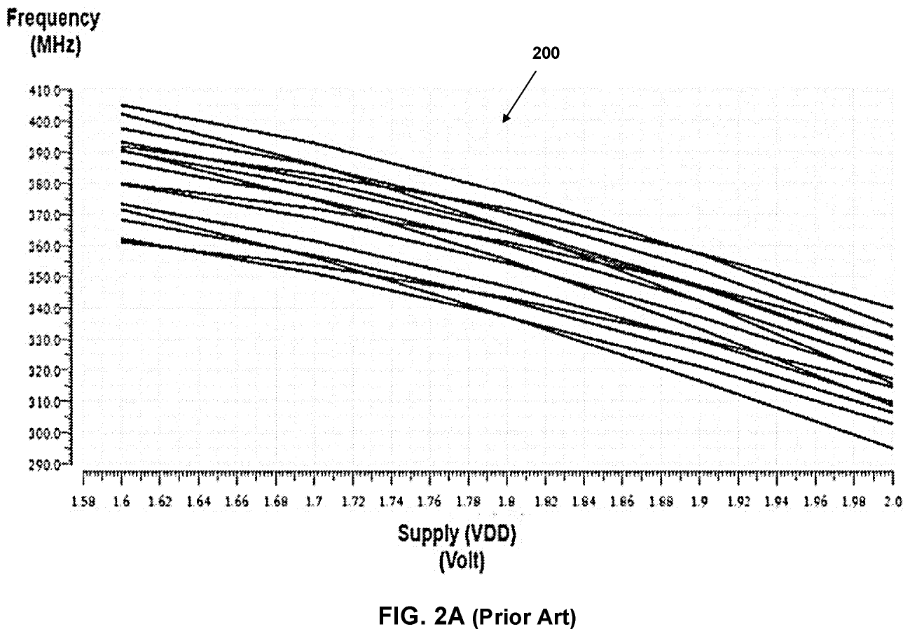

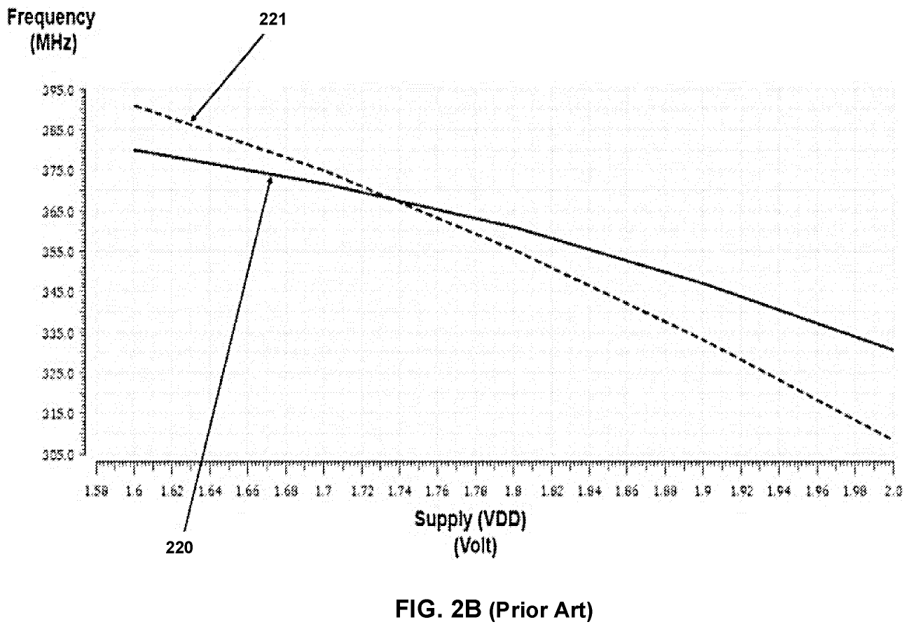

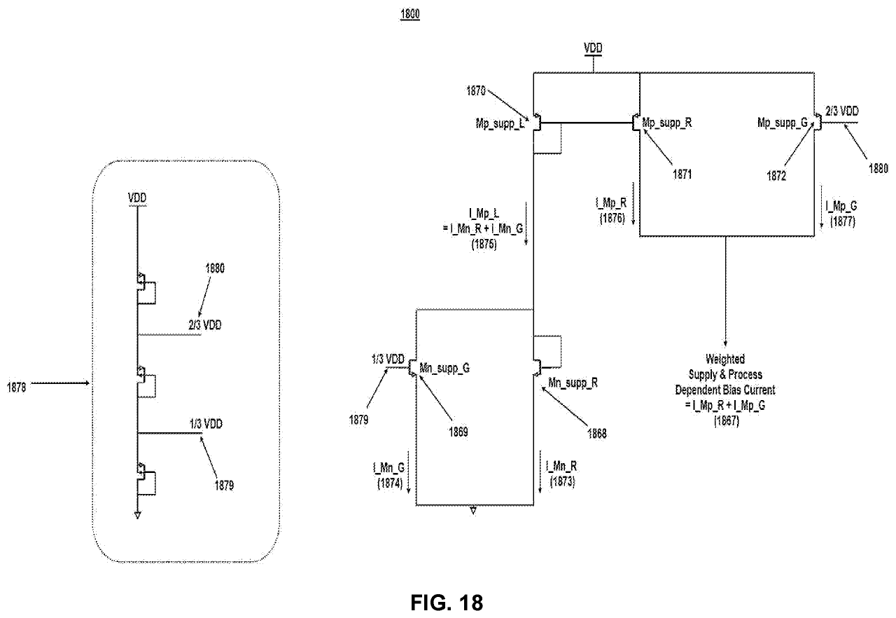

FIG. 18 shows a schematic block level circuit diagram of a Supply and Process dependent bias current generator (1800). The circuit generates a bias current (1867) that is directly proportional to the supply (VDD), and its slope and value depend on the MOSFET process corner. The aim of that bias current is to compensate the oscillator output clock frequency variation versus the supply (VDD) previously mentioned with reference to FIG. 2. The circuit consists of three parts mainly and a simple voltage divider as detailed below.

The first part includes two NMOS transistors: the first one is (Mn_supp_R) (1868), which is a diode connected NMOS transistor, and the second one is (Mn supp_G) (1869), the drain of which is connected to the drain of the transistor (Mn_supp_R) (1868) and its gate is connected to a portion of the supply (1879) (for example ⅓ VDD value).

The second part is a PMOS current mirror, which consists of two PMOS transistors. The first one is (Mp_supp_L) (1870), which is a diode connected PMOS transistor, the drain of which is connected to the drains of the NMOS transistors (Mn_supp_R and Mn_supp_G). The second transistor is (Mp_supp_R) (1871), the drain of which is connected to the output node of this circuit.

The third part is a PMOS transistor (Mp_supp_G) (1872), the drain of which is connected to the output node of this circuit and its gate is connected to a portion of the supply (1880) (for example ⅔ VDD).

The current (I_Mn_R) (1873) generated in the transistor (Mn_supp_R) (1868) is added to the current (I_Mn_G) (1874) generated in the transistor (Mn_supp_G) (1869) to be equal to the current (I_Mp_L) (1875) in the transistor (Mp_supp_L) (1870). The current (I_Mp_R) (1876) generated inside the transistor (Mp_supp_R) (1871) is a weighted copy of the current (I_Mp_L) (1875). The current (I_Mp_G) (1877) generated in the transistor (Mp_supp_G) (1872) is added to the current (I_Mp_R) (1876) to be the weighted supply and process dependent bias current (1867).

The circuit also includes a simple voltage divider (1878) that is used to generate portions of the supply (VDD). It is used to generate the gate voltage (1879) of the transistor (Mn_supp_G) (1869) (for example ⅓ VDD value) and the gate voltage (1880) of the transistor (Mp_supp_G) (1872) (for example ⅔ VDD value). The voltage divider (1878) can be implemented using series diode connected PMOS transistors as shown in the example of FIG. 18, or it can be implemented using resistors. If it is implemented using diode connected PMOS transistors, we have to make sure that there is a suitable current value flowing inside it (more than the leakage current) to have a robust design.

The output current is generally generated in this circuit when the supply (VDD) value is larger than (Vthn+Vthp), wherein (Vthn) is the threshold voltage of the NMOS transistor and (Vthp) is the threshold voltage of the PMOS transistor. For simplicity, we will consider here that Vthn=Vthp=Vth. Therefore, when the supply (VDD) value is less than 2Vth, all the transistors in this circuit are nearly off, so that the generated output current nearly equals zero.

When the supply (VDD) value is in the range of from 2Vth to 3Vth, the Vgs of the NMOS transistor (Mn_supp_G) (1869) is smaller than the threshold Vthn, so that it is nearly off and the current inside it (I_Mn_G) (1874) is almost zero. The same idea applies for the PMOS transistor (Mp_supp_G) (1872) at that supply range, wherein its Vsg is smaller than the threshold Vthp, so that it is nearly off and the current inside it (I_Mp_G) (1877) is almost zero. Thus, in that supply range, the current is generated in the NMOS diode connected transistor (Mn_supp_R) (1868) and PMOS diode connected transistor (Mp_supp_L) (1870). Therefore, the current (I_Mn_R) (1873) is equal to the current (I_Mp_L) (1875). The current (I_Mp_R) (1876) in the transistor (Mp_supp_R) (1871) is a weighted copy of the generated current (I_Mp_L) (1875). Therefore, in this case, the output current (1867) is equal to the current (I_Mp_R) (1876).

Because VDD=Vgs (Mn_supp_R)+Vsg (Mp_supp_L), when the supply (VDD) value increases, the Vgs of (Mn_supp_R) (1868) and the Vsg of (Mp_supp_L) (1870) increase, so that the current (I_Mp_L) (1875) (which is equal to (I_Mn_R)) increases, thereby the weighted current (I_Mp_R) (1876) increases and the generated output current (1867) increases. Therefore, the generated output current (supply and process dependent bias current) (1867) is directly proportional to the supply (VDD).

As the supply (VDD) value becomes greater than 3Vth, the Vgs of the NMOS transistor (Mn_supp_G) (1869) is greater than Vthn, and Vsg of the PMOS transistor (Mp_supp_G) (1872) is greater than Vthp, so that the current (I_Mn_G) (1874) is generated inside the transistor (Mn_supp_G) (1869) and this current increases as the supply (VDD) value increases. Also, the current (I_Mp_G) (1877) is generated inside the transistor (Mp_supp_G) (1872) and it increases as the supply (VDD) value increases. Therefore, in this case, the current (I_Mp_L) (1875) equals the sum of the two currents (I_Mn_R) (1873) and (I_Mn_G) (1874). The output generated current (1867) equals the sum of the two currents (I_Mp_R) (1876) and (I_Mp_G) (1877).

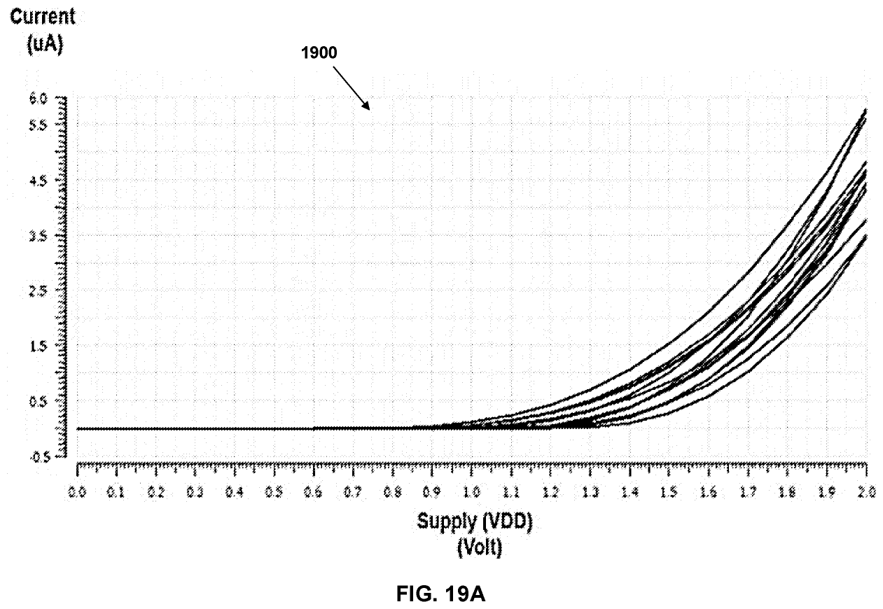

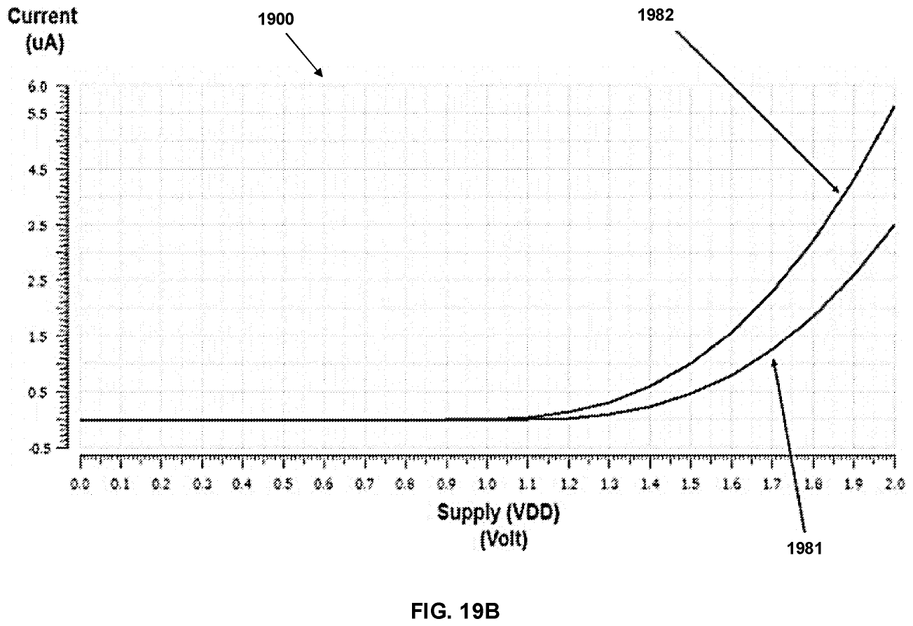

FIG. 19A shows the profile of the weighted supply and process dependent bias current versus the supply (VDD) for all process and temperature corners (1900). It is clear that the weighted supply and process dependent bias current is directly proportional to the supply (VDD) for all process and temperature corners, which fix the inverse proportionality of the current starved ring oscillator clock frequency versus the supply (VDD) previously mentioned with reference to FIG. 2. We can notice from the figure that the slopes of the generated currents are not the same for all the corners. These slopes depend on the MOSFET process corner. We can notice also that the generated current values are nearly equal to zero when the supply (VDD) value is less than 2Vth.

FIG. 19B shows the profile of the weighted supply and process dependent bias current versus the supply (VDD) at a typical temperature for the two MOSFET process corners: slow MOSFET corner (SS) (1981) and fast MOSFET corner (FF) (1982). It is clear that the slope of the generated current in the case of the fast MOSFET corner (FF) (1982) is steeper than the slope of the generated current in the case of the slow MOSFET corner (SS) (1981). The aim of such profile is to compensate the oscillator output clock frequency variation versus supply (VDD) for each MOSFET process corner (slow and fast corners). In case of the fast MOSFET corner (FF), the oscillator output clock frequency variation versus supply has a steeper (negative) slope (as discussed with reference to FIG. 2B), so that the generated current for this corner (1982) has a steeper (positive) slope to compensate the frequency variation, such that the oscillator output clock frequency remains nearly constant versus the supply (VDD) variation. In case of the slow MOSFET corner (SS), the oscillator output clock frequency variation versus supply has a small (negative) slope (as discussed with reference to FIG. 2B), so that the generated current for this corner (1981) has a small (positive) slope to compensate the frequency variation, such that the oscillator output clock frequency nearly remains constant versus the supply (VDD) variation.

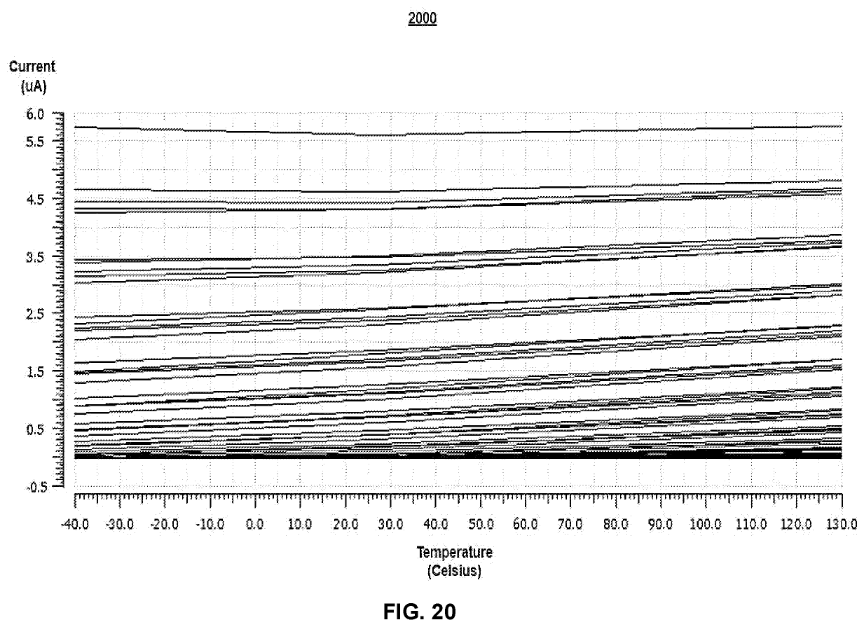

FIG. 20 shows a plot of the profile of the weighted supply and process dependent bias current versus the temperature for all process and supply (VDD) corners (2000). It is clear that the weighted supply and process dependent bias current values are a weak function of the temperature (it has a very small variation versus temperature). This small variation is due to the MOSFET threshold voltage variation across the temperature for each technology. However, this can be neglected because we are adding a weighted temperature dependent bias current in the generated adaptive bias current, wherein we can control the weight of the temperature dependent bias current (increase or decrease its portion) to adjust the oscillator output clock frequency variation versus temperature.

It is worth to mention that the MOSFET type (thin oxide, thick oxide, LVT, ULVT etc.) used in the bias generator can be suitably selected based on the VDD range and the correction profile needed for optimal frequency variation reduction over supply.

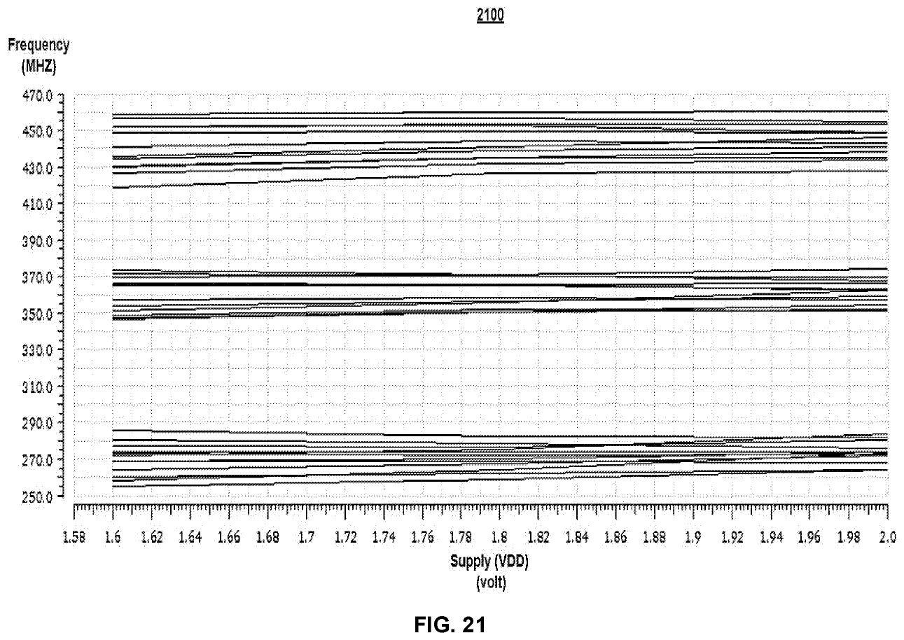

FIG. 21 shows a plot of untrimmed frequency variations of the oscillator output clock in the system of FIG. 10 versus the supply (VDD) for all process and temperature corners (2100). This is before doing the trimming We can see that the frequency is nearly constant (or has very small variation) versus the supply (VDD). This is because the generated adaptive bias current includes the weighted supply and process dependent bias current, which compensates the oscillator output clock frequency variation versus supply (VDD). Note that the oscillator output clock frequencies are not centered at 360 MHz in this example (the trimming is not done yet).

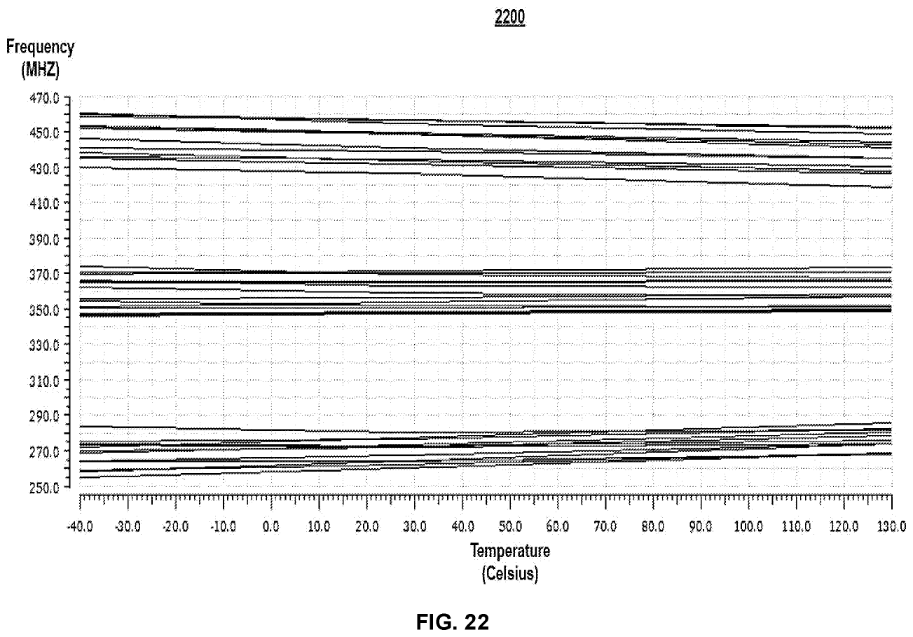

FIG. 22 shows a plot of the variation of the untrimmed frequency of the oscillator output clock in the system of FIG. 10 versus temperature for all process and supply (VDD) corners (2200). This is before doing the trimming We can see that the frequency is nearly constant (or has very small variation) versus the temperature. This is because the generated adaptive bias current includes weighted temperature dependent bias current, which compensates the oscillator output clock frequency variation versus temperature. Note that the oscillator output clock frequencies are not centered at 360 MHz in this example (the trimming is not done yet).

For the trimming, it is done one time only for each fabricated IC (for each process corner or each seed) at the typical temperature, typical supply (VDD) to adjust the frequency of the oscillator output clock at the desired value. That corresponds to the poly current trimming inside the adaptive bias current generator, wherein we increase the trimmed poly current to increase the frequency or decrease the trimmed poly current to decrease the frequency (based on the provided trimming code word), so that the frequency reaches the desired value. The trimmed poly current acts as a factor that shifts the oscillator output clock frequency up or down to adjust it to the desired value at the typical temperature and typical supply (VDD).

Then, after doing the trimming, as the supply (VDD) and the temperature change, the generated adaptive bias current will change to keep the oscillator output clock frequency nearly constant (at the trimmed frequency value). For example, if the temperature increases, the oscillator output clock frequency of the traditional current starved ring oscillator tends to decrease (as discussed with reference to FIG. 3), but at the same time, the generated adaptive bias current in the system will increase to compensate that (because the generated adaptive bias includes a weighted temperature dependent bias current that increases as the temperature increases). Therefore, the oscillator output clock frequency remains nearly constant (at the trimmed frequency value) versus the temperature variation. The same idea applies for the supply (VDD) variation. For example, if the supply value (VDD) increases, the oscillator output clock frequency of the traditional current starved ring oscillator tends to decrease (as discussed with reference to FIG. 2), but at the same time, the generated adaptive bias current in the system will increase to compensate that (because the generated adaptive bias includes the weighted supply and process dependent bias current that increases as the supply increases). Therefore, the oscillator output clock frequency remains nearly constant (at the trimmed frequency value) versus the supply variation. The slope of the weighted supply and process dependent bias current depends also on the MOSFET process corner, whether slow MOSFET corner (SS) or fast MOSFET corner (FF) (as discussed with reference to FIG. 19B), so that it compensates precisely the oscillator output clock frequency variation versus supply for each process corner with a specific slope, so that the oscillator output clock frequency remains nearly constant at the trimmed frequency value.

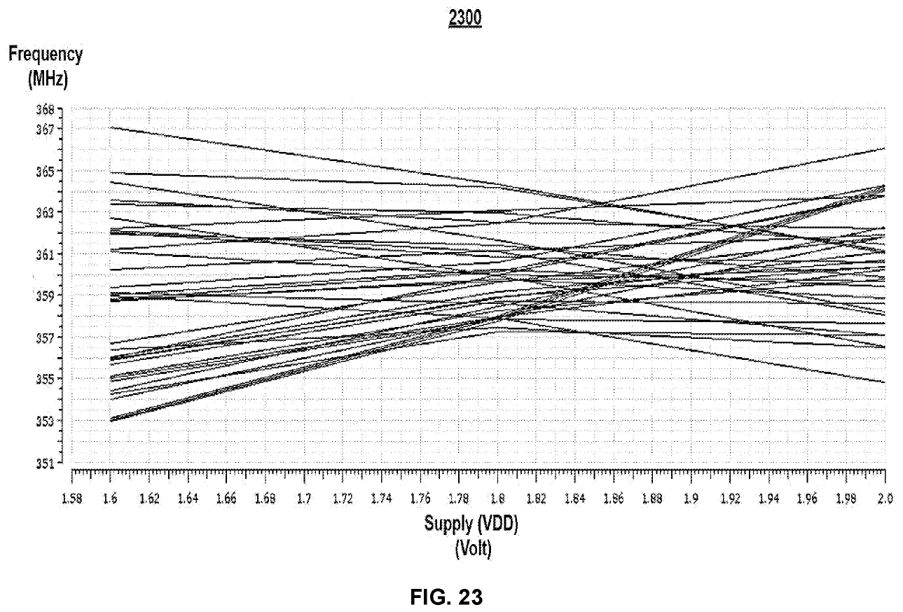

FIG. 23 shows a plot of the variations of the trimmed frequencies of the oscillator output clock in the system of FIG. 10 versus the supply (VDD) for all process and temperature corners after doing the trimming (2300). The oscillator output clock frequency is trimmed to be 360 MHz at a typical supply and typical temperature. We can see that the trimmed frequencies are nearly constant (or has very small variations) versus the supply (VDD) for all process and temperature corners. This is because the generated adaptive bias current includes the weighted supply and process dependent bias current that compensates the oscillator output clock frequency variation versus supply (VDD). Note that the frequency is centered at 360 MHz (trimmed frequency value) with accuracy better than 2%.

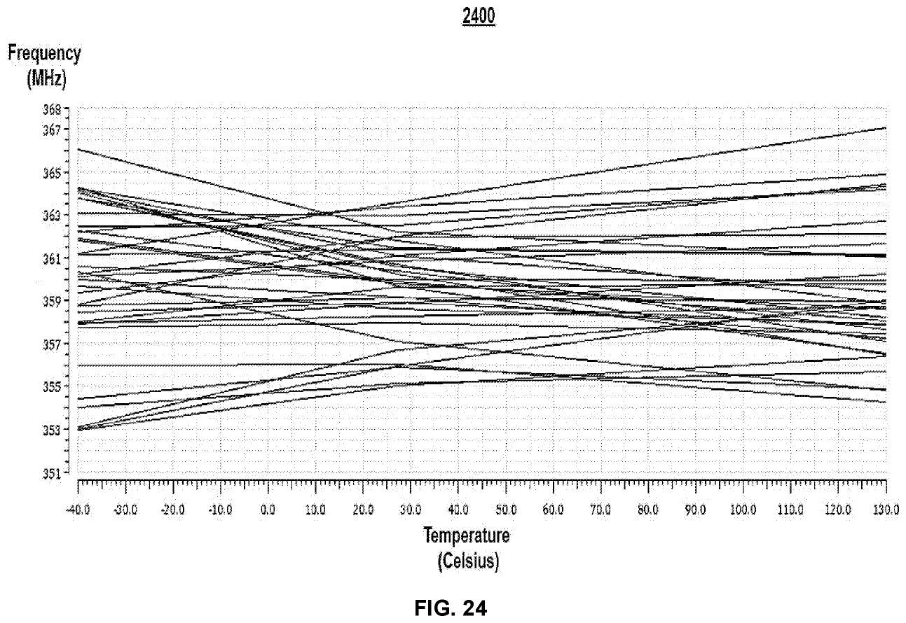

FIG. 24 shows a plot of the variations of the trimmed frequencies of the oscillator output clock in the system of FIG. 10 versus the temperature for all process and temperature corners after doing the trimming (2400). The oscillator output clock frequency is trimmed to be 360 MHz at a typical supply and typical temperature. We can see that the trimmed frequencies are nearly constant (or have very small variations) versus the temperature for all process and supply (VDD) corners. This is because the generated adaptive bias current includes the weighted temperature dependent bias current that compensates the oscillator output clock frequency variation versus the temperature. Note that the frequency is centered at 360 MHz (trimmed frequency value) with accuracy better than 2%.

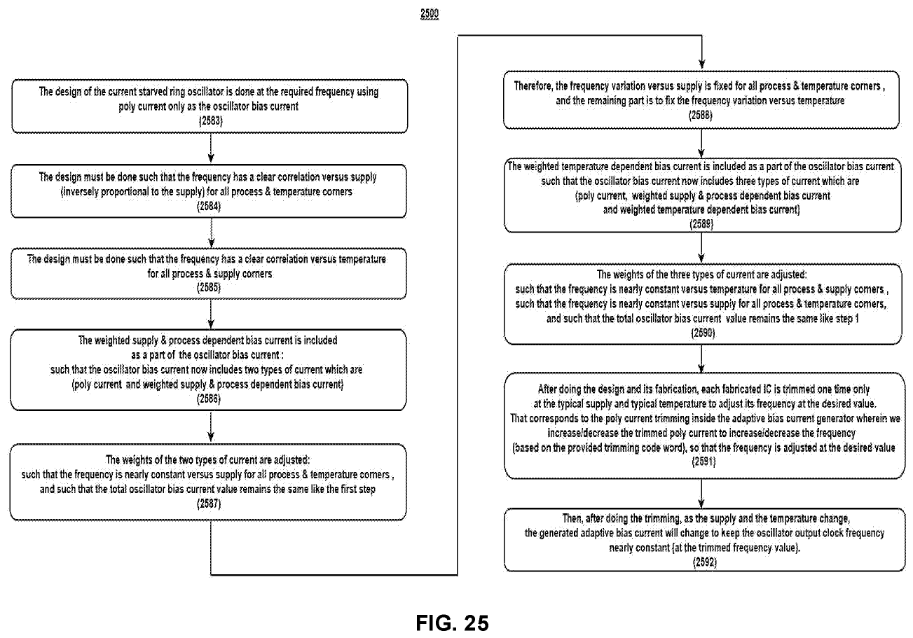

FIG. 25 shows a flow chart (2500) that illustrates the design steps and the operation of a current starved ring oscillator using an adaptive bias technique that compensates the oscillator output clock frequency variation versus supply, temperature, and process. First, the design of the current starved ring oscillator is performed at the required frequency using a poly current only as the oscillator bias current (2583). The design should be done such that the oscillator output clock frequency has a clear correlation versus supply (VDD) (inversely proportional to the supply) for all process and temperature corners (2584). In addition, the design should be done such that the oscillator output clock frequency has a clear correlation versus temperature (inversely proportional to the temperature or directly proportional to temperature based on the technology used) for all process and supply corners (2585). Then, the weighted supply and process dependent bias current is included as a part of the oscillator bias current such that the oscillator bias current now includes two types of currents, which are a poly current and a weighted supply and process dependent bias current (2586). The weights of the two types of currents are adjusted such that the oscillator output clock frequency is nearly constant versus supply (VDD) for all process and temperature corners such that the total oscillator bias current value remains the same as in the first step (2587). Therefore, the oscillator output clock frequency variation versus supply (VDD) is fixed for all process and temperature corners, and the remaining part is to fix the oscillator output clock frequency variation versus temperature (2588). Then, the weighted temperature dependent bias current is included as a part of the oscillator bias current such that the bias current used now includes three types of currents, which are poly current, weighted supply and process dependent bias current, and weighted temperature dependent bias current (2589). Then, the weights of the three types of currents are adjusted such that the oscillator output clock frequency is nearly constant versus temperature for all process and supply corners such that the oscillator output clock frequency is nearly constant versus supply (VDD) for all process and temperature corners, and such that the total used bias current value remains the same as in the first step (2590). After doing the design and its fabrication, each fabricated IC is trimmed one time only at the typical supply (VDD) and typical temperature to adjust its frequency at the desired value. The trimming corresponds internally to the poly current trimming inside the adaptive bias current generator, wherein we increase/decrease the trimmed poly current to increase/decrease the frequency (based on the provided trimming code word), so that the frequency is adjusted to the desired value (2591). Then, after doing the trimming, as the supply (VDD) and the temperature change, the generated adaptive bias current will change to keep the oscillator output clock frequency nearly constant (at the trimmed frequency value), e.g., with an accuracy better than 2% around the trimmed frequency value across the supply and temperature variations (2592).

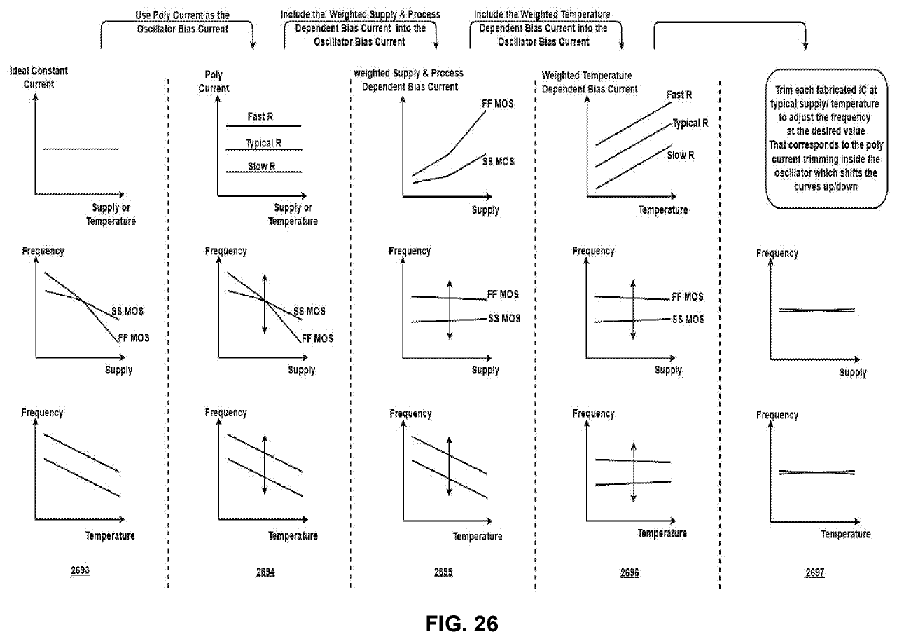

FIG. 26, using various graph illustrations, shows a summary (2600) of the design and operations outlined in FIG. 25. At the start (2693), for a simple current starved ring oscillator using constant ideal current as its bias current, it was shown that the oscillator output clock frequency is inversely proportional to the supply (VDD) for all process a temperature corners wherein, the frequency of the fast MOSFET corner (FF) has a steeper negative slope versus the supply (VDD) compared to that of the slow MOSFET corner (SS). It was shown also that the oscillator output clock frequency is inversely proportional to the temperature for all process & supply corners (based on the technology used). The second step (2694) is to use a poly current (Vbgref/R_poly) as the oscillator bias current, wherein the poly current is nearly constant across the supply (VDD) and temperature. The value of the poly current depends on the process corner of the poly resistor (R_poly). As a result, all the frequency curves will shift up or down based on the value of the poly current. The third step (2695) is to include the weighted supply and process dependent bias current as a part of the oscillator bias current such that the oscillator bias current now includes two types of currents, which are a poly current and a weighted supply and process dependent bias current. The weights of the two types of currents are adjusted such that the oscillator output clock frequency is nearly constant versus supply for all process and temperature corners and such that the total oscillator bias current value remains the same. As a result of that, it is shown that the oscillator output clock frequency is nearly constant versus supply (VDD) for all process and temperature corners. However, it is shown that the oscillator output clock frequency still has variation versus temperature (inversely proportional to the temperature) for all process and supply corners. Note that all the curves still have shift up or down. The fourth step (2696) is to include the weighted temperature dependent bias current (e.g., a weighted PTAT bias current) as a part of the oscillator bias current such that the oscillator bias current now includes three types of currents which are a poly current , a weighted supply and process dependent bias current, and a weighted temperature dependent bias current. Then, the weights of the three types of currents are adjusted such that the oscillator output clock frequency is nearly constant versus temperature for all process and supply corners, such that the oscillator output clock frequency is nearly constant versus supply for all process and temperature corner, and such that the total oscillator bias current value remains the same. As a result of that, it is shown that the oscillator output clock frequency is nearly constant versus supply (VDD) for all process and temperature corners. It is shown also that the oscillator output clock frequency is nearly constant versus temperature for all process and supply corners. Note that all the curves still have shift up or down. The last step (2697) is the fabrication and then doing the trimming for each fabricated IC. The trimming is done one time only at the typical supply and typical temperature to adjust the oscillator output clock frequency to the desired value. The trimming corresponds internally to the poly current trimming in the adaptive bias current generator. Increasing the trimmed poly current shifts up the frequency and decreasing it shifts the frequency down. Thus, doing the trimming compensates for the process variations (MOSFET, Capacitors, and Resistors). Then, after doing the trimming, as the supply changes, the adaptive bias current will change to keep the oscillator output clock frequency nearly constant (at the trimmed frequency value) versus the supply (VDD) variation. The same idea applies for the temperature. As the temperature changes, the adaptive bias current will change to keep the oscillator output clock frequency nearly constant (at the trimmed frequency value) versus temperature variation. Therefore, it is shown that the oscillator output clock frequency is nearly constant versus supply and the curve is centered at the trimmed frequency value with no shift up or down. It is shown also that the oscillator output clock frequency is nearly constant versus the temperature and the curve is centered at the trimmed frequency value with no shift up or down.

It is worth mentioning that the same design technique can be used with various other types of oscillators (for example, relaxation oscillators, LC oscillators, etc.). In addition, the system can operate using the supply VDD directly or it can also operate using a regulated supply, i.e., a supply generated by a voltage regulator (for example, a low dropout linear regulator “LDO”, a DCDC converter, etc.).

While the invention has been described with respect to a limited number of embodiments, those skilled in the art, having the benefit of this disclosure, will appreciate that other embodiments can be devised which do not depart from the scope of the invention as disclosed herein. Accordingly, the scope of the invention should be limited only by the attached claims.

What is claimed is:

1. An apparatus comprising:
a poly current generator circuit for generating a poly current, wherein the poly current generator circuit comprises:
a fractional bandgap circuit that generates the poly current, or
a bandgap voltage reference circuit and a current reference generator, wherein the bandgap voltage reference circuit generates a bandgap voltage reference as an input for the current reference generator, wherein the current reference generator comprises a regulation loop that comprises a resistor and an error amplifier, wherein the current reference generator uses the regulation loop and the bandgap voltage reference to generate the poly current, wherein the poly current has a value that depends on a value of the resistor and the bandgap voltage reference,
wherein the poly current is independent of a supply (VDD);
an adaptive bias current generator configured to use the poly current to generate an adaptive bias current that is adaptive to variations in supply, temperature, and process such that a value of the adaptive bias current changes based on the variations in the supply, the temperature, and the process;
a frequency generator is configured to use the adaptive bias current as an input to generate an output clock signal having a select frequency, wherein the frequency generator comprises a current starved ring oscillator that comprises n identical cascaded stages connected in a shape of a ring, wherein an output of the nth cascaded stage is fed back as an input of the first cascaded stage, wherein n is an odd number greater than or equal to 3; and clock buffers configured to buffer the output clock signal generated by the frequency generator for distribution.

2. The apparatus of claim 1, wherein the bandgap voltage reference circuit generates a voltage reference independent of the supply, temperature and process corners, wherein the bandgap voltage reference circuit is a traditional bandgap circuit or the fractional bandgap circuit, wherein the bandgap voltage reference circuit is implemented using resistors and BJTs, or the bandgap voltage reference circuit is all CMOS bandgap voltage reference circuit.

3. The apparatus according to claim 1, wherein each of the n identical cascaded stages is a current starved inverter that comprises an inverting module, an NMOS current source, and a PMOS current source,
wherein the inverting module is configured to output an inverted version of an input received by the inverting module, wherein the inverting module comprises one NMOS transistor and one PMOS transistor, wherein a source of the PMOS transistor is connected via the PMOS current source to the supply, and a source of the NMOS transistor is connected via the NMOS current source to a ground, wherein drains of both the PMOS transistor and the NMOS transistor are connected together to an output of a current starved inverter stage, wherein gates of both the NMOS transistor and the PMOS transistor are connected together to the input of the current starved inverter stage,
wherein the NMOS current source and the PMOS current source are used to bias the inverting module, wherein both the NMOS current source and the PMOS current source carry the same value of a current that is a copy or a weighted copy of the adaptive bias current generated by the adaptive bias current generator,
wherein the NMOS transistor and the PMOS transistor are MOSFET devices, and
wherein an oscillator output clock frequency depends on the bias current that is a copy or a weighted copy of the adaptive bias current.

4. The apparatus according to claim 1, wherein the adaptive bias current generator consists of four circuits that comprise a poly current weighting circuit, a poly current trimming circuit, a temperature dependent bias current generator, and a supply and process dependent bias current generator,
wherein the poly current weighting circuit takes the poly current generated from the current reference generator circuit and creates an internal weighted copy of the poly current, which is used by the poly current trimming circuit,
wherein the poly current trimming circuit takes the weighted copy of the poly current and a trimming code word to generate the trimmed poly current based on the trimming code word,
wherein the temperature dependent bias current generator generates a weighted temperature dependent bias current, wherein the weighted temperature dependent bias current is a complementary to absolute temperature (CTAT) current or a proportional to absolute temperature (PTAT) current, such that a value of the weighted temperature dependent bias current is independent of the supply value.

5. The apparatus of claim 1, wherein the current reference generator is a circuit that generates a poly current through a regulation loop including an error amplifier and a resistor; such that the value of the generated poly current depends on the values of the used resistor and the bandgap voltage reference; and such that the generated poly current value is independent on the supply and it has very small variation (or nearly constant) versus temperature variations. The used error amplifier architecture can be a folded cascade error amplifier or any other topology.

6. The apparatus of claim 1, wherein the current reference generator can be removed if the bandgap voltage reference circuit is a fractional bandgap circuit which generates poly current; in this case, the generated poly current from the fractional bandgap circuit is provided directly to the adaptive bias current generator.

7. The apparatus of claim 1, wherein the adaptive bias current generator consists of four circuits that comprises a poly current weighting circuit, a poly current trimming circuit, a temperature dependent bias current generator, and a supply and process dependent bias current generator, wherein the adaptive bias current by the adaptive bias current generator is used to bias the current starved ring oscillator.

8. The apparatus of claim 1, wherein the poly current weighting circuit (inside the adaptive bias current generator) takes the generated poly current from the current reference generator and creates an internal weighted copy of it which will be used by the poly current trimming circuit; the poly current weighting circuit can be a simple current mirror or cascade current mirror. The value of the weighted poly current depends on the ratio of the used current mirror.

9. The apparatus of claim 1, wherein the poly current trimming circuit (inside the adaptive bias current generator) takes the weighted copy of the poly current and the provided trimming code word to generate the trimmed poly current based on the trimming code word; it can be a binary weighted (n bits) current DAC wherein the current mirrors inside the current DAC can be simple current mirrors or cascade current mirrors. The value of the trimmed poly current depends on the provided trimming code word.

10. The apparatus of claim 1, wherein the temperature dependent bias current generator (inside the adaptive bias current generator) generates a weighted temperature dependent bias current whose value depends on the temperature; it can be a CTAT current or PTAT current. The value of the generated weighted temperature dependent bias current is independent on the supply value. The aim of this current is to fix the oscillator output clock frequency variation versus the temperature. The PTAT current generator can be a constant GM bias circuit wherein the generated current inside it is a PTAT current. The CTAT current generator can be implemented using a BJT, diode connected MOSFET which acts as a BJT, resistor and error amplifier wherein the CTAT current=(VBE/resistor value). If the oscillator output clock frequency (without using this bias current) is inversely proportional to the temperature, a PTAT current is generated here. If the oscillator output clock frequency (without using this bias current) is directly proportional to the temperature, a CTAT current is generated here. The weight of the generated temperature dependent bias current is adjusted in the circuit design such that it compensates the oscillator output clock frequency variation versus the temperature across all process and supply corners; such that the oscillator output clock frequency remains nearly constant across the temperature for all the process and supply corners.

11. The apparatus of claim 1, wherein the supply & process dependent bias current generator (inside the adaptive bias current generator) generates a weighted supply & process dependent bias current which is directly proportional to the supply and its value & slope (versus the supply) is dependent on the process corner of the MOSFET. The aim of this generated bias current is to fix the oscillator output clock frequency variation versus the supply. The supply & process dependent bias current generator consists mainly of two NMOS transistors, three PMOS transistors and a simple voltage divider. The first NMOS transistor is a diode connected one whose source is connected to the ground, and its drain is connected to the drain for the second NMOS transistor. For the second NMOS transistor, its source is connected to the ground, its drain is connected to the drain of the first NMOS, and its gate is connected to a portion of the supply (for example ⅓ supply value). The first PMOS transistor is a diode connected one whose source is connected to the supply; its drain is connected to the drain of the first and second NMOS transistors. For the second PMOS transistor, its source is connected to the supply, its gate is connected to the gate of the first PMOS transistor and its drain is connected to the output node of this circuit. The first and the second PMOS transistors act together like a current mirror. For the third PMOS transistor, its source is connected to the supply, its drain is connected to the output node of the circuit and its gate is connected to a portion of the supply (for example ⅔ supply value). The generated current in the first PMOS transistor is equal to the sum of the generated currents in the first NMOS transistor and the second NMOS transistors. The generated current in the second PMOS transistor is a weighted copy of the current in the first PMOS transistor (depending on the ratio of the current mirror). The generated weighted supply & process dependent bias current is equal to the sum of the generated currents in the second PMOS transistor and the third PMOS transistor. The voltage divider is used to generate portions of the supply. It is used to generate the gate voltage of the second NMOS transistor and the gate voltage of the third PMOS transistor. The voltage divider can be implemented using series diode connected PMOS transistors or it can be implemented using resistors. The NMOS and PMOS in the bias generator in general can be any type of MOSFET such as thin gate or thick gate devices with any VT type (such as LVT or ULVT etc. . . . ) and the choice of device is made in such a way that the desired correction current profile is achieved for the range of supply in which the frequency variation of the oscillator with supply is to be minimized

12. The apparatus of claim 1, wherein the frequency generator comprises a current starved ring oscillator having a plurality of (n) identical cascaded stages connected together in a shape of a ring and generating an output clock signal having a certain frequency such that the output of the nth stage is fed back to be the input of the first stage; wherein the number of the stages (n) is an odd number greater than or equal 3; wherein each stage is a current starved inverter which comprises an inverting module, an NMOS current source, a PMOS current source; Wherein the NMOS current source which is used to bias the inverting module can be a simple current source or a cascade current source; wherein the PMOS current source which is used to bias the inverting module can be a simple current source or a cascade current source; wherein both the NMOS current source and the PMOS current source carry the same value of current which is a copy (or weighted copy) of the generated adaptive bias current which is generated by the adaptive bias current generator; wherein the oscillator output clock frequency depends on the used bias current; which is a copy (or weighted copy) of the generated adaptive bias current;

13. The apparatus of claim 1, wherein the clock buffers are used to buffer the output clock signal that is generated by the frequency generator; so that the clock can be distributed to the whole system; the clock buffers can be simple inverters to buffer the clock to different loads with very sharp rise/fall time.

14. A method comprising:
generating a voltage reference using a bandgap voltage reference circuit, wherein the voltage reference is provided as an input to a current reference generator;
generating a poly current using the current reference generator uses the bandgap voltage reference to generate a poly current through a regulation loop including a resistor and an error amplifier, such that the value of the generated poly current depends on the values of the used resistor and the bandgap voltage reference; and such that the generated poly current value is independent on the supply and it has very small variation (or nearly constant) versus temperature variations
generating, using an adaptive bias current generator, an adaptive bias current that is adaptive to the supply, temperature and process variations which means that the generated adaptive bias current value changes based on the variations in the supply, temperature and process;
providing the generated adaptive bias current as an input to a frequency generator such that the frequency generator uses the generated adaptive bias current as its bias current; wherein the frequency generator comprises a current starved ring oscillator having a plurality of n identical cascaded stages connected together in a shape of a ring and generating an output clock signal having a certain frequency such that the output of the nth stage is fed back to be the input of the first stage; wherein the number of the stages (n) is an odd number greater than or equal 3; wherein each stage is a current starved inverter which comprises an inverting module, an NMOS current source, a PMOS current source; wherein the inverting module is configured to output an inverted version of its received input; the inverting module comprises one NMOS transistor and one PMOS transistor , such that the source of the PMOS transistor is connected via the PMOS current source to the supply , the source of the NMOS transistor is connected via the NMOS current source to the ground, the drains of both PMOS and NMOS transistors are connected together to the output of the current starved inverter stage, the gates of both NMOS and PMOS transistors are connected together to the input of the current starved inverter stage; wherein the NMOS current source is used to bias the inverting module; wherein the PMOS current source is used to bias the inverting module; wherein both the NMOS current source and the PMOS current source carry the same value of current which is a copy (or weighted copy) of the generated adaptive bias current which is generated by the adaptive bias current generator; wherein the oscillator output clock frequency depends on the used bias current; which is a copy (or weighted copy) of the generated adaptive bias current; the clock buffers are used to buffer the output clock signal that is generated by the frequency generator; so that the clock can be distributed to the whole system; the adaptive bias current generator (that generates the adaptive bias current) consists of four circuits which are poly current weighting circuit, poly current trimming circuit, temperature dependent bias current generator, and supply & process dependent bias current generator; wherein the poly current weighting circuit takes the generated poly current from the current reference generator and creates an internal weighted copy of it which will be used by the poly current trimming circuit; wherein the poly current trimming circuit takes the weighted copy of the poly current and the provided trimming code word to generate the trimmed poly current based on the trimming code word; wherein the temperature dependent bias current generator generates a weighted temperature dependent bias current whose value depends on the temperature; it can be a CTAT current or PTAT current. The value of the generated weighted temperature dependent bias current is independent on the supply value. The aim of this current is to fix the oscillator output clock frequency variation versus the temperature. If the oscillator output clock frequency (without using this bias current) is inversely proportional to the temperature, a PTAT current is generated here. If the oscillator output clock frequency (without using this bias current) is directly proportional to the temperature, a CTAT current is generated here. The weight of the generated temperature dependent bias current is adjusted in the circuit design such that it compensates the oscillator output clock frequency variation versus the temperature across all process and supply corners; such that the oscillator output clock frequency remains nearly constant across the temperature for all the process and supply corners; wherein the supply & process dependent bias current generator generates a weighted supply & process dependent bias current which is directly proportional to the supply and its value & slope (versus the supply) is dependent on the process corner of the MOSFET. The generated bias current has a certain slope in the case of the Fast MOSFET corner (FF) different than the case of the slow MOSFET corner (SS). The aim of this generated bias current is to fix the oscillator output clock frequency variation versus the supply; since for a current starved ring oscillator (without using this bias current), the frequency is inversely proportional to the supply wherein the frequency for each MOSFET process corner is having a different slope against the supply. The weight of the generated current is adjusted such that it compensates the oscillator output clock frequency variation versus the supply for all temperature and process corners; such that the oscillator output clock frequency variation remains nearly constant across the supply for all process and temperature corners; the generated adaptive bias includes three types of currents added together in certain weights which are the trimmed poly current, the weighted temperature dependent bias current and the weighted supply & process dependent bias current; wherein the trimmed poly current value is nearly constant versus supply and versus temperature variation; it acts like a component which shifts up/down the frequency of the oscillator by increasing/decreasing the trimmed poly current through the provided trimming code word; such that the oscillator output clock frequency is adjusted during the trimming to the desired value; wherein the weighted temperature dependent bias current value depends on the temperature; it can be a CTAT current or PTAT current. The value of the generated weighted temperature dependent bias current is independent on the supply value. The aim of this current is to fix the oscillator output clock frequency variation versus temperature; its weight is adjusted in the circuit design such that it compensates the oscillator output clock frequency variation versus the temperature for all supply and process corners; such that the oscillator output clock frequency is nearly constant across temperature for all process and supply corners; wherein the weighted supply & process dependent bias current is directly proportional to the supply and its value & slope depends on the MOSFET process corner. The aim of this current is to fix the oscillator output clock frequency variation versus supply; its weight is adjusted in the circuit design such that it compensates the oscillator output clock frequency variation versus the supply for all temperature and process corners; such that the oscillator output clock frequency is nearly constant across supply for all process and temperature corners; the trimming is done for each fabricated IC one time at the typical supply and typical temperature to adjust the oscillator output clock frequency at the desired value; that corresponds internally to the poly current trimming; wherein the trimmed poly current is increased/decreased to shift up/down the frequency (based on the trimming code word), so that the frequency is adjusted at the desired value; then, after doing the trimming, as the supply changes, the adaptive bias current will change to keep the frequency nearly constant (at the trimmed frequency value) versus the supply variation. The same idea is applied for the temperature, as the temperature changes, the adaptive bias current will change to keep the frequency nearly constant (at the trimmed frequency value) versus temperature variation such that oscillator output clock frequency nearly remains constant (with accuracy better than 2% around the trimmed frequency value) across supply and temperature variations.

15. The method of claim 12,
Wherein the bandgap voltage reference circuit is a circuit that generates a voltage reference independent of the supply, temperature and process corners; the bandgap voltage reference circuit architecture can be any topology like the traditional one or the fractional bandgap circuit. It can be implemented using resistors and BJTs or it can be all CMOS bandgap voltage reference circuit.

16. The method of claim 12,
Wherein the current reference generator a circuit that generates a poly current through a regulation loop including an error amplifier and a resistor; such that the value of the generated poly current depends on the values of the used resistor and the bandgap voltage reference; and such that the generated poly current value is independent on the supply and it has very small variation (or nearly constant) versus temperature variations. The used error amplifier architecture can be a folded cascade error amplifier or any other topology.

17. The method of claim 12,
Wherein the current reference generator can be removed if the bandgap voltage reference circuit is a fractional bandgap circuit which generates poly current; in this case, the generated poly current from the fractional bandgap circuit is provided directly to the adaptive bias current generator.

18. A method comprising:
designing a current starved ring oscillator (frequency generator) at a required frequency using poly current only as the oscillator bias current such that the oscillator output clock frequency has a clear correlation versus supply (inversely proportional to the supply) across all process & temperature corners. Also, the design is done such that the oscillator output clock frequency has a clear correlation versus temperature (inversely proportional to the temperature or directly proportional to temperature based on the used technology) across all process & supply corners;
providing a weighted supply & process dependent bias current as a part of the oscillator bias current such that the oscillator bias current now includes two types of current which are (poly current and weighted supply & process dependent bias current). The weights of the two types of current are adjusted; such that the oscillator output clock frequency is nearly constant versus supply for all process & temperature corners, and such that the total oscillator bias current value remains the same like the first step. Therefore, the oscillator output clock frequency variation versus supply is fixed for all process & temperature corners, and the remaining part is to fix the oscillator output clock frequency variation versus temperature;
providing a weighted temperature dependent bias current as a part of the oscillator bias current; such that the used bias current now includes three types of current which are (poly current, weighted supply & process dependent bias current and weighted temperature dependent bias current). Then, the weights of the three types of current are adjusted; such that the oscillator output clock frequency is nearly constant versus temperature for all process & supply corners; such that the oscillator output clock frequency is nearly constant versus supply for all process & temperature corners such that the total oscillator bias current value remains the same as the first step; and
after doing the design and its fabrication, trimming each fabricated IC one time only at the typical supply (VDD) and typical temperature to adjust its frequency at the desired value. That corresponds internally to the poly current trimming inside the adaptive bias current generator wherein the trimmed poly current is increased/decreased to shift up/down increase/decrease the frequency (based on the provided trimming code word), so that the frequency is adjusted at the desired value. Then, after doing the trimming, as the supply and the temperature change, the generated adaptive bias current will change to keep the oscillator output clock frequency nearly constant (at the trimmed frequency value) with accuracy better than 2% around the trimmed frequency value across supply and temperature variation.
